(19) United States
(12) Patent Application Publication
(10) Pub. No.: US 2022/0106524 A1
(43) Pub. Date: Apr. 7, 2022

(54) LIQUID CRYSTAL COMPOSITION, LIQUID CRYSTAL LAYER, LAMINATE, AND IMAGE DISPLAY DEVICE

(71) Applicant: FUJIFILM Corporation, Tokyo (JP)

(72) Inventors: Hiroyuki OKUSA, Kanagawa (JP); Naoya SHIBATA, Kanagawa (JP); Hiroshi MATSUYAMA, Kanagawa (JP); Tadashi KAJIYA, Kanagawa (JP); Naoki HAYASHI, Kanagawa (JP)

(73) Assignee: FUJIFILM Corporation, Tokyo (JP)

(21) Appl. No.: 17/554,568

(22) Filed: Dec. 17, 2021

Related U.S. Application Data
(63) Continuation of application No. PCT/JP2020/025560, filed on Jun. 29, 2020.

(30) Foreign Application Priority Data
Jul. 3, 2019 (JP) 2019-124450
Feb. 19, 2020 (JP) 2020-025988

(51) Int. Cl. C09K 19/54; C09K 19/38; C09K 19/56; C09K 19/60; G02B 5/30; H01L 51/52

(52) U.S. Cl. CPC C09K 19/542; C09K 19/3852; C09K 19/56; C09K 2019/528; G02B 5/3016; H01L 51/5281; C09K 19/601

(57) ABSTRACT

Provided is a liquid crystal composition and a liquid crystal layer, each having an excellent alignment degree, a laminate including the liquid crystal layer, and an image display device using the same. The liquid crystal composition includes at least a liquid crystalline compound and a surfactant, in which the surfactant is a copolymer having a repeating unit including an alkyl fluoride group and a repeating unit including a ring structure, and a content of fluorine of the surfactant is 32% by mass or more.

### CROSS-REFERENCE TO RELATED APPLICATIONS

This application is a Continuation of PCT International Application No. PCT/JP2020/025560 filed on Jun. 29, 2020, which, claims priority under 35 U.S.C. § 119(a) to Japanese Patent Application No. 2019-124450 filed on Jul. 3, 2019 and Japanese Patent Application No. 2020-025988 filed on Feb. 19, 2020. Each of the above applications is hereby expressly incorporated by reference, in its entirety, into the present application.

### BACKGROUND OF THE INVENTION

### 1. Field of the Invention

The present invention relates to a liquid crystal composition, a liquid, crystal layer, a laminate, and an image display device.

### 2. Description of the Related Art

Optical films such as an optical compensation sheet, a phase difference film, and a circularly polarizing plate are used in various image display devices from the viewpoints of elimination of image coloring, expansion of a viewing angle, prevention of reflection, and the like, hut each member used therefor is required to be made thinner.

A stretched birefringence film has been, used as the optical compensation sheet or the phase difference film. Although these have been designed to enhance the aligning properties of materials by stretching, there has been a limit in making the film thinner in order to express desired refractive index anisotropy.

In addition, in the related art, an iodine polarizer has been used in a circularly polarizing plate. The iodine polarizer has been produced by dissolving iodine, adsorbing the iodine onto a film of a high-molecular-weight material such as polyvinyl alcohol, and stretching the film at a high magnification in one direction, and it has thus been difficult to make the film sufficiently thinner.

In recent years, it has been proposed to make an optically anisotropic layer (liquid crystal layer) thinner, using a liquid crystalline compound instead of the stretched birefringence film.

In addition, with regard to the iodine polarizer, a polarizing element in which a liquid crystalline compound or a dichroic azo coloring agent is applied onto a substrate such as a transparent film and aligned using an intermolecular interaction or the like has been investigated. For example, WO2018/124198A proposes a polarizing element having a high alignment degree by increasing the crystallinity of a dichroic azo coloring agent compound using a specific liquid crystalline compound.

JP2006-16599A proposes to suppress the occurrence of alignment defects near a surface by incorporating a (meth)acryl copolymer (surfactant) having a specific structure with a content of fluorine groups (content of fluorine) of 30% or less into a liquid crystal layer near an air interface.

### SUMMARY OF THE INVENTION

It is generally known that a surfactant is required in order to obtain an excellent, planar coating film. The present inventors have investigated various surfactants as a surfactant to be blended into a liquid crystal composition, and have thus found that an alignment degree of a liquid crystal layer formed of the liquid crystal composition is not sufficient depending on a type of the surfactant, and there is therefore room for improvement.

Therefore, an object of the present invention is to provide a liquid crystal composition capable of forming a liquid crystal layer having an excellent alignment degree, a liquid crystal layer, a laminate, and an image display device.

The present inventors have conducted intensive investigations to accomplish the object, and have thus found that a liquid crystal layer having a high alignment degree can be obtained by adding a specific surfactant to a liquid crystal composition that forms the liquid crystal layer, thereby completing the present invention.

That is, the present inventors have found that the object can be accomplished by the following configurations.

[1] A liquid crystal composition comprising at least:

a liquid crystalline compound;

a surfactant; and

a dichroic substance,

in which the surfactant is a copolymer having a repeating unit including an alkyl fluoride group and a repeating unit including a ring structure, and a content of fluorine of the surfactant is 32% by mass or more.

[2] The liquid crystal composition as described in [1],

in which a content of the dichroic substance is 2 to 200 parts by mass with respect to 100 parts by mass of the liquid crystalline compound.

[3] The liquid crystal composition as described in [1] or [2],

in which the repeating unit including a ring structure is a repeating unit including two or more ring structures.

[4] The liquid crystal composition as described in any one of [1] to [3],

in which the repeating unit including a ring structure includes a group represented by Formula (ca) which will be described later.

In Formula (ca) which will be described later, A, B, and C which are each a 6-membered ring each independently represent any of Formulae (ca1) to (ca10) which will be described later, Y₁ and Y₂ each independently represent a single bond, —CH₂CH₂—, —CH₂O—, —OCH₂—, —COO—, —OCO—, —C≡C—, —CH═CH—, —CF═CF—, —(CH₂)₄—, —CH₂CH₂CH₂O—, —OCH₂CH₂CH₂—, —CH₂═CHCH₂CH₂—, or —CH₂CH₂CH═CH—, Y₃ represents a hydrogen atom, a halogen atom, a cyano group, an alkyl group having 1 to 20 carbon atoms, an alkoxy group, an alkenyl group, or an alkenyloxy group, n represents an integer of 0 or 1, and * represents a bonding position to another group.

In Formulae (ca1) to (ca10) which will be described later, * represents a bonding position to another group, a left-side bonding site corresponds to a left-side bonding site in A, B, and C of Formula (ca) which will be described later, and a right-side bonding site corresponds to a right-side bonding site in A, B, and C of Formula (ca) which will be described later. A hydrogen atom bonded to a carbon atom constituting a ring in each of Formulae (ca1) to (ca10) which will be described later may be substituted with, a fluorine atom or a methyl group.

[5] The liquid crystal composition as described in any one of [1] to [4],

in which a dispersion term δd of a Hansen solubility parameter of the surfactant is in a range of 15.5 to 17.5.

[6] The liquid crystal composition as described in any one of [1] to [5], in which the liquid crystalline compound is a high-molecular-weight liquid crystalline compound.

[7] A liquid crystal layer formed of the liquid crystal composition as described in any one of [1] to [6].

[8] A laminate comprising at least:

a photoalignment layer; and

the liquid crystal layer as described in [7] provided on the photoalignment layer,

in which the liquid crystalline compound included in the liquid crystal layer is immobilized in a horizontally aligned state.

[9] The laminate as described in [8],

in which a content of the dichroic substance included in the liquid crystal layer is 3% to 35% by mass with respect to a total solid content of the liquid crystal layer.

[10] The laminate as described in [8] or [9], in which the photoalignment layer contains a compound having a photoaligned group, and the photoaligned group is a group having a cinnamoyl structure.

[11] The laminate as described in any one of [8] to [10], further comprising λ/4 plate provided on the liquid crystal layer.

[12] An image display device comprising:

the laminate as described in any one of [8] to [11]; and

an image display element.

[13] The image display device as described in [12],

in which the image display element is an organic EL display element.

According to the present invention, it is possible to provide a liquid crystal composition capable of forming a liquid crystal layer having an excellent alignment degree, a liquid crystal layer, a laminate, and an image display device.

### BRIEF DESCRIPTION OF THE DRAWINGS

FIG. 1 is a schematic cross-sectional view showing an example of a laminate of an embodiment of the present invention.

FIG. 2 is a schematic cross-sectional view showing an example of the laminate of the embodiment of the present invention.

### DESCRIPTION OF THE PREFERRED EMBODIMENTS

Hereinafter, the present invention will be described in detail.

Description of configuration requirements described below may be made based on representative embodiments of the present invention, but the present invention is not limited to such embodiments.

Furthermore, in the present specification, a numerical range expressed using “to” means a range which includes the preceding and succeeding numerical values of to as a lower limit value and an upper limit value, respectively.

In addition, in the present specification, being parallel, being orthogonal, being horizontal, and being perpendicular do not mean being parallel, being orthogonal, being horizontal, and being perpendicular in strict meanings, respectively, but mean a range of being parallel±10°, a range of being orthogonal±10°, a range of being horizontal±10°, and a range of being perpendicular±10°, respectively.

Moreover, in the present specification, as each component, a substance corresponding to each component may be used alone or in combination of two or more kinds thereof. Here, in a case where two or more kinds of substances are used in combination tor each component, a content of the component refers to a total content of the substances used in combination unless otherwise specified.

Moreover, in the present specification, “(meth)acrylate” is a notation representing “acrylate” or “methacrylate”, “(meth)acryl” is a notation representing “acryl” or “methacryl”, and “(meth)acryloyl” is a notation representing “acryloyl” or “methacryloyl”.

(Method for Measuring In-Plane Average Refractive Index)

An in-plane average refractive index is measured using a spectroscopic ellipsometer M-2000U manufactured by J. A. Woollam. A direction in which, a refractive index is maximum in the plane is defined as an x axis, a direction orthogonal to the direction is defined as a y axis, a normal direction with respect to the in-plane is defined as a z axis, and the refractive indices in the respective directions are defined as nₓ, n_{y}, and n_{z}. The in-plane average refractive index (nₐᵥₑ) in the present invention is represented by Expression (1).

nₐᵥₑ=(nₓ+n_{y})/2 Expression (1)

[Liquid Crystal Composition]

The liquid crystal composition of an embodiment of the present invention contains at least a liquid crystalline compound, a surfactant, and a dichroic substance, furthermore, the surfactant is a copolymer having a repeating unit including an alkyl fluoride group and a repeating unit including a ring structure. In addition, a content or fluorine of the surfactant is 32% by mass or more.

With the liquid crystal composition of the embodiment of the present invention, a liquid crystal layer having an excellent alignment degree can be formed.

Details of a reason thereof have not been clarified yet, but the present inventors have speculated that the reason is to be as follows.

In a case where a liquid crystal composition is applied onto a support or an alignment layer to form a liquid crystal layer, one surface of the liquid crystal layer is formed such that the surface is in contact with air. In a case where a liquid crystal composition containing no surfactant is used, the alignment of the liquid crystal compound tends to be disturbed near a surface (on the air interface side) of the obtained liquid crystal layer.

With regard to this problem, it is considered that in a case where a surfactant having a repeating unit including a ring structure is used, the surfactant is likely to be located near a surface of the liquid crystal layer (on the air interface side), the liquid crystal compound is farther from the air interface, and as a result, the alignment detects could be suppressed.

On the other hand, it is presumed that in a stats where the liquid crystalline compound is aligned to a high degree (specifically in a state where the alignment degree is 0.90 or more in a method for evaluating the alignment degree which will be described later), even a slight mixing of the surfactant in a region in which the liquid crystalline compound is aligned inhibits the alignment of the liquid crystal compound near a surface of the liquid crystal layer (on the air interface side).

It is considered that in the present invention, by using a copolymer which has a repeating unit including an alkyl fluoride group and a repeating unit including a ring structure and has a content of fluorine of 32% by mass or more as the surfactant, the uneven distribution properties of a surface of the surfactant is enhanced and the alignment inhibition of the liquid crystalline compound can be suppressed, whereby a liquid crystal layer having an excellent alignment degree can be obtained.

Hereinafter, each component included in the liquid crystal composition of the embodiment of the present invention will be described in detail.

<Liquid Crystalline Compound>

The liquid crystal composition of the embodiment of the present invention contains a liquid, crystalline compound.

The liquid crystalline compound is preferably a liquid crystalline compound which does not exhibit dichroism in the visible region.

As the liquid crystalline compound, both of a low-molecular-weight liquid crystalline compound and a high-molecular-weight liquid crystalline compound can be used. Here, the “low-molecular-weight liquid crystalline compound” refers to a liquid crystalline compound having no repeating unit in the chemical structure. In addition, the “high-molecular-weight liquid crystalline compound” refers to a liquid crystalline compound having a repeating unit in the chemical structure.

Examples of the low-molecular-weight liquid crystalline compound include the liquid crystalline compounds described in JP2013-228706A.

Examples of the high-molecular-weight liquid crystalline compound include the thermotropic liquid crystalline polymers described in JP2011-237513A. Moreover, the high-molecular-weight liquid crystalline compound may have a crosslinkable group (for example, an acryloyl group and a methacryloyl group) at the terminal.

The liquid crystalline compound may be used alone or in combination of two or more kinds thereof.

A content of the liquid crystalline compound is preferably 25 to 2,000 parts by mass, more preferably 33 to 1,000 parts by mass, and still more preferably 50 to 500 parts by mass with respect to 100 parts by mass of a content of the dichroic substance in the liquid crystal composition. By setting the content of the liquid crystalline compound to be within the range, the alignment degree of the liquid crystal layer is further improved.

(Repeating Unit (1))

For a reason that the alignment degree of the obtained liquid crystal layer is further enhanced, the liquid crystalline compound is preferably a high-molecular-weight liquid crystalline compound, and more preferably a high-molecular-weight liquid crystalline compound including a repeating unit represented by Formula (1) (hereinafter also referred to as a “repeating unit (1)”).

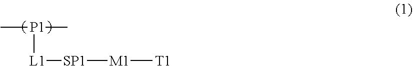

In Formula (1), P1 represents a main chain of the repeating unit, L1 represents a single bond or a divalent linking group, SP1 represents a spacer group, M1 represents a mesogenic group, and T1 represents a terminal group.

Specific examples of the main chain of the repeating unit represented by P1 include groups represented by Formulae (P1-A) to (P1-D), and among these, the group represented by Formula (P1-A) is preferable from the viewpoints of a diversity of monomers used as raw materials and easy handling.

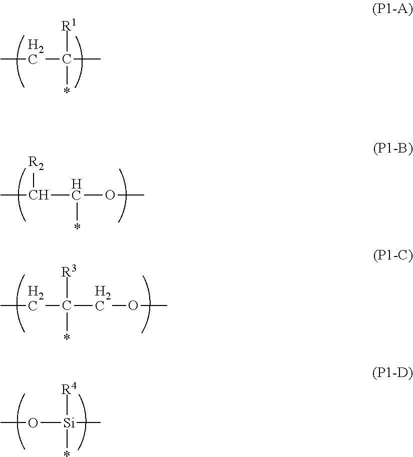

In Formulae (P1-A) to (P1-D), represents a bonding position to L1 in Formula (1). In Formulae (P1-A) to (P1-D), R¹, R², R³, and R⁴ each independently represent a hydrogen atom, a halogen atom, an alkyl group having 1 to 10 carbon atoms, or an alkoxy group having 1 to 10 carbon atoms. The alkyl group may be a linear or branched alkyl group, or may be an alkyl group (cycloalkyl group) having a cyclic structure. Moreover, the number of carbon atoms in the alkyl group is preferably 1 to 5.

A group represented by Formula (P1-A) is preferably one unit of a partial structure of poly(meth)acrylic acid ester obtained by polymerization of (meth)acrylic acid ester.

A group represented by Formula (P1-B) is preferably an ethylene glycol unit formed by ring-opening polymerization of an epoxy group of a compound having the epoxy group.

A group represented by Formula (P1-C) is preferably a propylene glycol unit formed by ring-opening polymerization of an oxetane group of a compound having the oxetane group.

A group represented by Formula (P1-D) is preferably a siloxane unit of a polysiloxane obtained by condensation polymerization of a compound having at least one group of an alkoxysilyl group or a silanol group. Here, examples of the compound having at least one group of an alkoxysilyl group or a silanol group include a compound having a group represented by a formula of SiR⁴(OR⁵)₂—. In the formula, R⁴ has the same definition as R in Formula (P1-D), and a plurality of R⁵'s each independently represent a hydrogen atom or an alkyl group having 1 to 10 carbon atoms.

L1 is a single bond or a divalent linking group.

Examples of the divalent linking group represented by L1 include —C(O)O—, —OC(O)—, —O—, —S—, —C(O)NR³—, —NR³C(O)—, —S(O)₂—, and —NR³R⁴—. In the formulae, R³ and R⁴ each independently represent a hydrogen atom, or an alkyl group having 1 to 6 carbon atoms, which may have a substituent (for example, a substituent W which will be described later). In the specific example of the divalent linking group, the left-side bonding site is bonded to P1 and the right-side bonding site is bonded to SP1.

In a case where P1 is the group represented by Formula (P1-A), L1 is preferably a group represented by —C(O)O— for a reason that the alignment degree of the obtained liquid crystal layer is higher.

In a case where P1 is the group represented by each of Formulae (P1-B) to (P1-D), L1 is preferably the single bond for a reason that the alignment degree of the obtained liquid crystal layer is higher.

The spacer group represented by SP1 is preferably a group including at least one kind of structure selected from the group consisting of an oxyethylene structure, an oxypropylene structure, a polysiloxane structure, and an alkylene fluoride structure, or a linear or branched alkylene group having 2 to 20 carbon atoms. It should be noted that the alkylene group may include —O—, —O—CO—, —CO—O—, or —O—CO—O—.

For reasons of easy exhibition of liquid crystallinity, availability of a raw material, and the like, the spacer group represented by SP1 is preferably a group including at least one structure selected from the group consisting of an oxyethylene structure, an oxypropylene structure, a polysiloxane structure, and an alkylene fluoride structure.

Here, the oxyethylene structure represented by SP1 is preferably a group represented by *—(CH₂—CH₂O)ₙ₁—*. In the formula, n1 represents an integer of 1 to 20, and * represents a bonding position to L1 or M1 in Formula (1). For a reason that the alignment degree of the obtained liquid crystal layer is higher, n1 is preferably an integer of 2 to 10, more preferably an integer of 2 to 4, and most preferably 3.

In addition, for a reason that the alignment degree of the obtained liquid crystal layer is higher, the oxypropylene structure represented by SP1 is preferably a group represented by *—(CH(CH₃)—CH₂O)ₙ₂—*. In the formula, n2 represents an integer of 1 to 3, and * represents a bonding position to L1 or M1.

In addition, for a reason that the alignment degree of the obtained liquid crystal layer is higher, the polysiloxane structure represented by SP1 is preferably a group represented by *—(Si(CH₃)₂—O)ₙ₃—*. In the formula, n3 represents an integer of 6 to 10, and * represents a bonding position to L1 or M1.

In addition, for a reason that the alignment degree of the obtained liquid crystal layer is higher, the alkylene fluoride structure represented by SP1 is preferably a group represented by *—(CF₂—CF₂)ₙ₄—*. In the formula, n4 represents an integer of 6 to 10, and * represents a bonding position to L1 or M1.

The mesogenic group represented by M1 is a group indicating a main skeleton, of a liquid crystal molecule which contributes to liquid crystal formation. The liquid crystal molecule exhibits liquid crystallinity which, is an intermediate state (mesophase) between a crystalline state and an isotropic liquid state. The mesogenic group is not particularly limited, and reference can be made to, for example, “Flussige Knstalle in Tabellen II” (VEB Deutsche Verlag fur Grundstoff Industrie, Leipzig, published in 1984), particularly the descriptions on pages 7 to 16, and Editorial committee of Liquid Crystal Handbook, liquid crystal handbook (Maruzen Publishing Co., Ltd., published in 2000), particularly the descriptions in Chapter 3.

As the mesogenic group, for example, a group having at least one kind of cyclic structure selected from the group consisting of an aromatic hydrocarbon group, a heterocyclic group, and an alicyclic group is preferable.

For a reason that the alignment degree of the obtained liquid crystal layer is higher, the mesogenic group preferably has aromatic hydrocarbon groups, more preferably has two to four aromatic hydrocarbon groups, and still more preferably has three aromatic hydrocarbon groups.

As the mesogenic group, from the viewpoints of exhibition of liquid crystallinity, adjustment of a liquid crystal phase transition temperature, availability of a raw material, and synthesis suitability, and for a reason that the effect, of the present invention is more excellent, a group represented by Formula (M1-A) or Formula (M1-B) is preferable, and the group represented by Formula (M1-B) is more preferable.

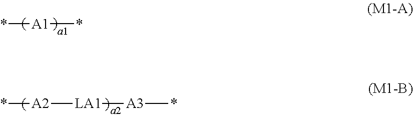

In Formula (M1-A), A1 is a divalent group selected from the group consisting of an aromatic hydrocarbon group, a heterocyclic group, and an alicyclic group. These groups may be substituted with an alkyl group, an alkyl fluoride group, an alkoxy group, or a substituent.

The divalent group represented by A1 is preferably a 4- to 6-membered ring. Moreover, the divalent group represented by A1 may be monocyclic or condensed cyclic.

* represents a bonding position to SP1 or T1.

Examples of the divalent aromatic hydrocarbon group represented by A1 include a phenylene group, a naphthylene group, a fluorene-diyl group, an anthracene-diyl group, and a tetracene-diyl group, and from the viewpoint of a diversity of design of a mesogenic skeleton, availability of a raw material, or the like, a phenylene group or a naphthylene group is preferable and a phenylene group is more preferable.

The divalent heterocyclic group represented by A1 may be either aromatic or non-aromatic, but is preferably a divalent aromatic heterocyclic group from the viewpoint that the alignment degree is further improved.

Examples of atoms which constitute the divalent aromatic heterocyclic group and are other than carbon include a nitrogen atom, a sulfur atom, and an oxygen atom. In a case where the aromatic heterocyclic group has a plurality of atoms which constitute a ring and art other than carbon, these atoms may be the same as or different from each other.

Specific examples of the divalent, aromatic heterocyclic group include a pyridylene group (pyridine-diyl group), a pyridazine-diyl group, an imidazole-diyl group, a thienylene group (thiophene-diyl group), a quinolylene group (quinoline-diyl group), an isoquinolylene group (isoquinoline-diyl group), an oxazole-diyl group, a thiazole-diyl group, an oxadiazole-diyl group, a benzothiazole-diyl group, a benzothiadiazole-diyl group, a phthalimido-diyl group, a thienothiazole-diyl group, a thiazolothiazole-diyl group, a thienothiophene-diyl group, and a thienooxazole-diyl group.

Specific examples of the divalent alicyclic group represented by A1 include a cyclopentylene group and a cyclohexylene group.

In Formula (M1-A), a1 represents an integer of 1 to 10. In a case where a1 is 2 or more, a plurality of A1's may be the same as or different from each other.

In Formula (M1-B), A2 and A3 are each independently a divalent group selected from the group consisting of an aromatic hydrocarbon group, a heterocyclic group, and an alicyclic group. Specific examples and suitable aspects of A2 and A3 are the same as those of A1 in Formula (M1-A), and thus descriptions thereof will be omitted.

In Formula (M1-B), a2 represents an integer of 1 to 10, and in a case where a2 is 2 or more, a plurality of A2's may be the same as or different from each other, a plurality of A3's may be the same as or different from each other, and a plurality of LA1's may be the same as or different from each other. For a reason that the alignment degree of the obtained liquid crystal layer is higher, a2 is preferably an integer of 2 or more, and more preferably 2.

In Formula (M1-B), in a case where a2 is 1, LA1 is a divalent linking group. In a case where a2 is 2 or more, the plurality of LA1's are each independently a single bond or a divalent linking group, and at least one among the plurality of LA1 s is a divalent linking group. In a case where a2 is 2, it is preferable that one of two LA1 s is the divalent linking group and the other is the single bond for a reason that the alignment degree of the obtained liquid crystal layer is higher.

In Formula (M1-B), examples of the divalent linking group represented by LA1 include —O—, —(CH₂)_{g}—, —(CF₂)_{g}—, —Si(CH₃)₂—, —(Si(CH₃)₂O)_{g}—, —(OSi(CH₃)₂)ᵣ (g represents an integer of 1 to 10), —N(Z)—, —C(Z)═C(Z′)—, —C(Z)═N—, —N═C(Z)—, —C(Z)₂—C(Z′)₂—, —C(O)—, —OC(O)—, —C(O)O—, —O—C(O)O—, —N(Z)C(O)—, —C(O)N(Z)—, —C(Z)═C(Z′)—C(O)O—, —O—C(O)—C(Z)═C(Z′)—, —C(Z)═N—, —N═C(Z)—, —C(Z)═C(Z′)—C(O)N(Z″)—, —N(Z″)—C(O)—C(Z)═C(Z′)—, —C(Z)═C(Z′)—C(O)—S—, —S—C(O)—C(Z)═C(Z′)—, —C(Z)═N—N═C(Z′)— (Z, Z′, and Z″ independently represent hydrogen, a C1 to C4 alkyl group, a cycloalkyl group, an aryl group, a cyano group, or a halogen atom), —C≡C—, —N═N—, —S—, —S(O)—, —S(O)(O)—, —(O)S(O)O—, —O(O)S(O)O—, —SC(O)—, and —C(O)S—. Among those, for a reason that the alignment degree of the obtained liquid crystal layer is higher, —C(O)O— is preferable, LA1 may be a group obtained by combining two or more of these groups.

Specific examples of M1 include the following structures. Moreover, in the following specific examples, “Ac” represents an acetyl group,

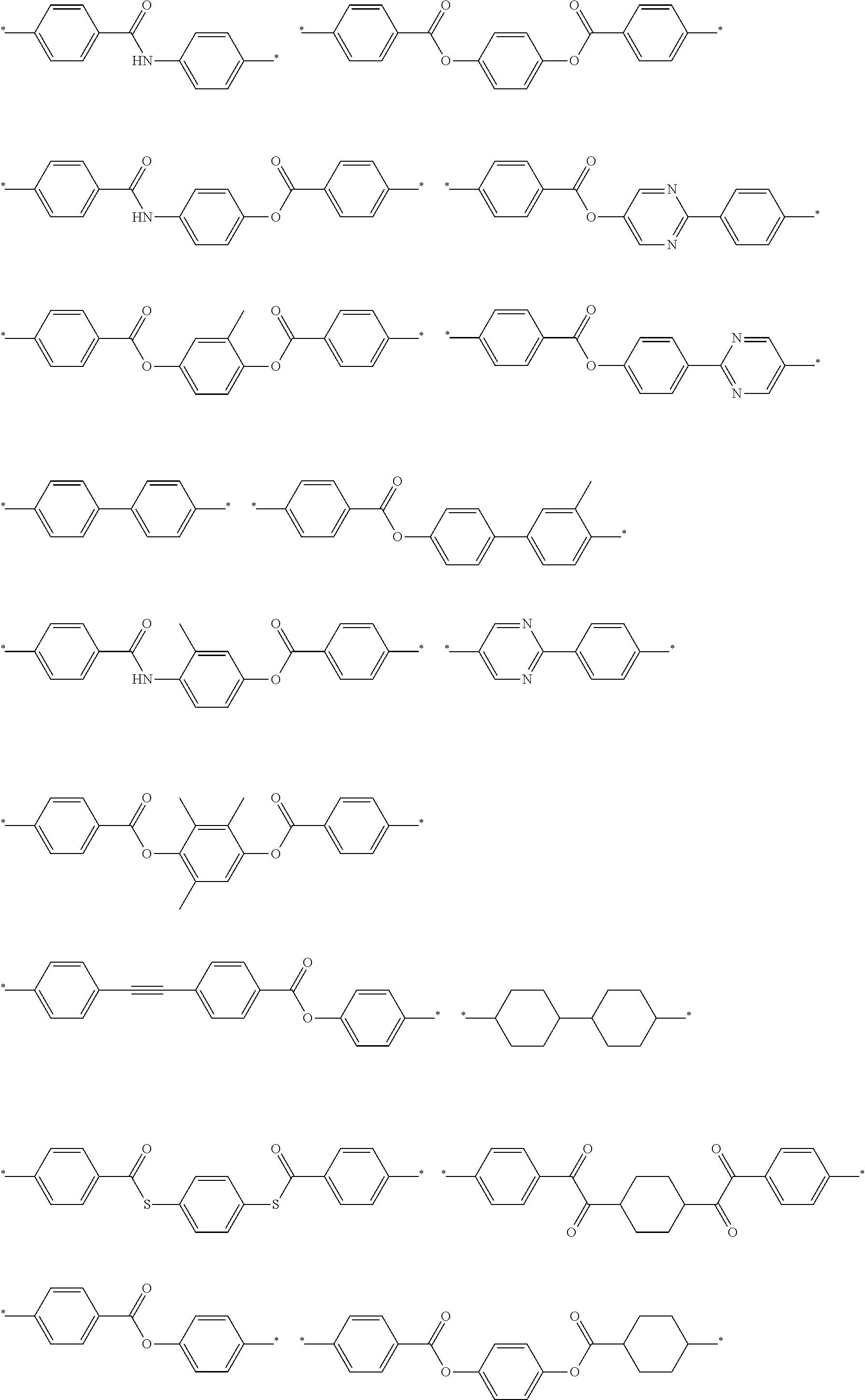

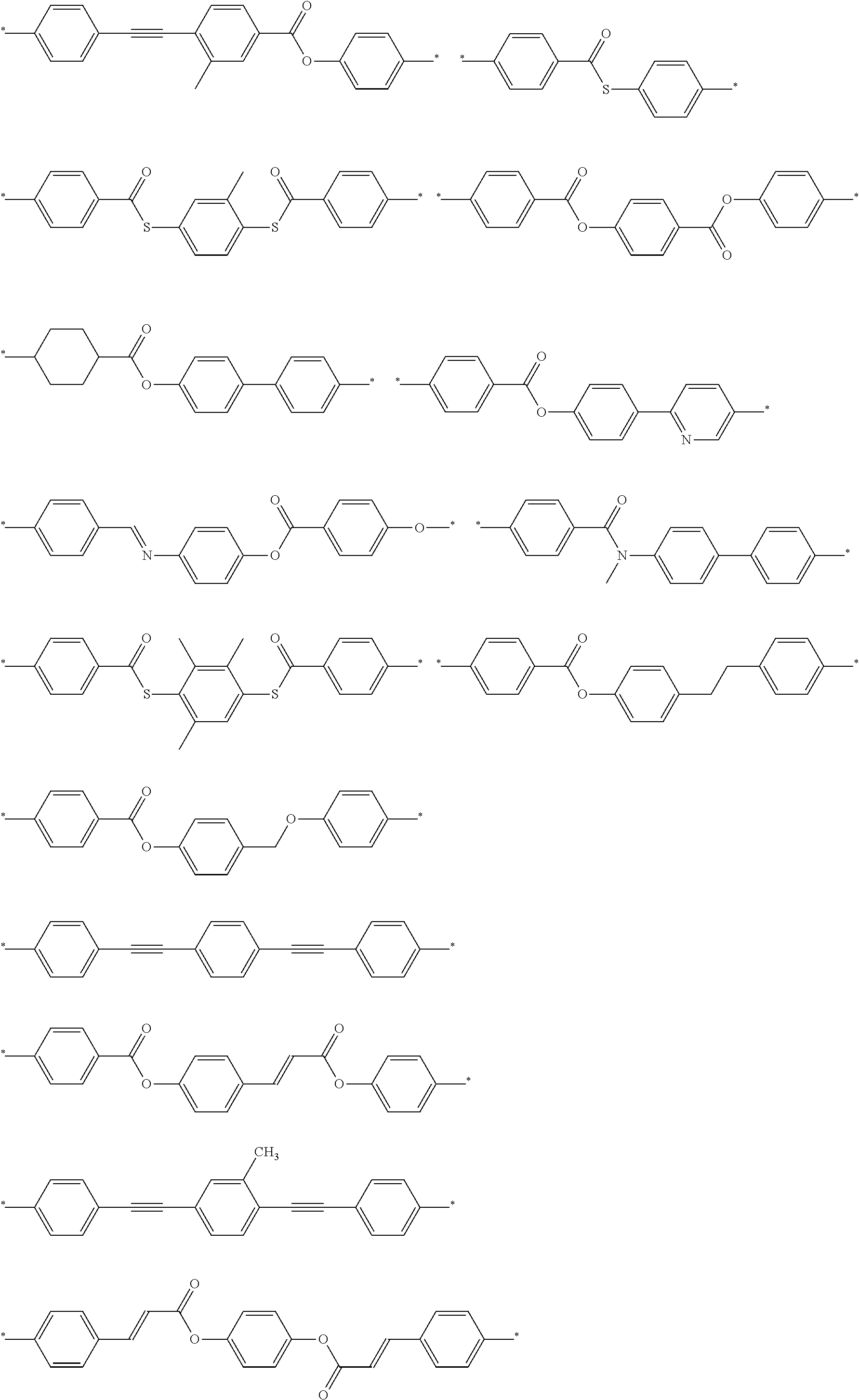

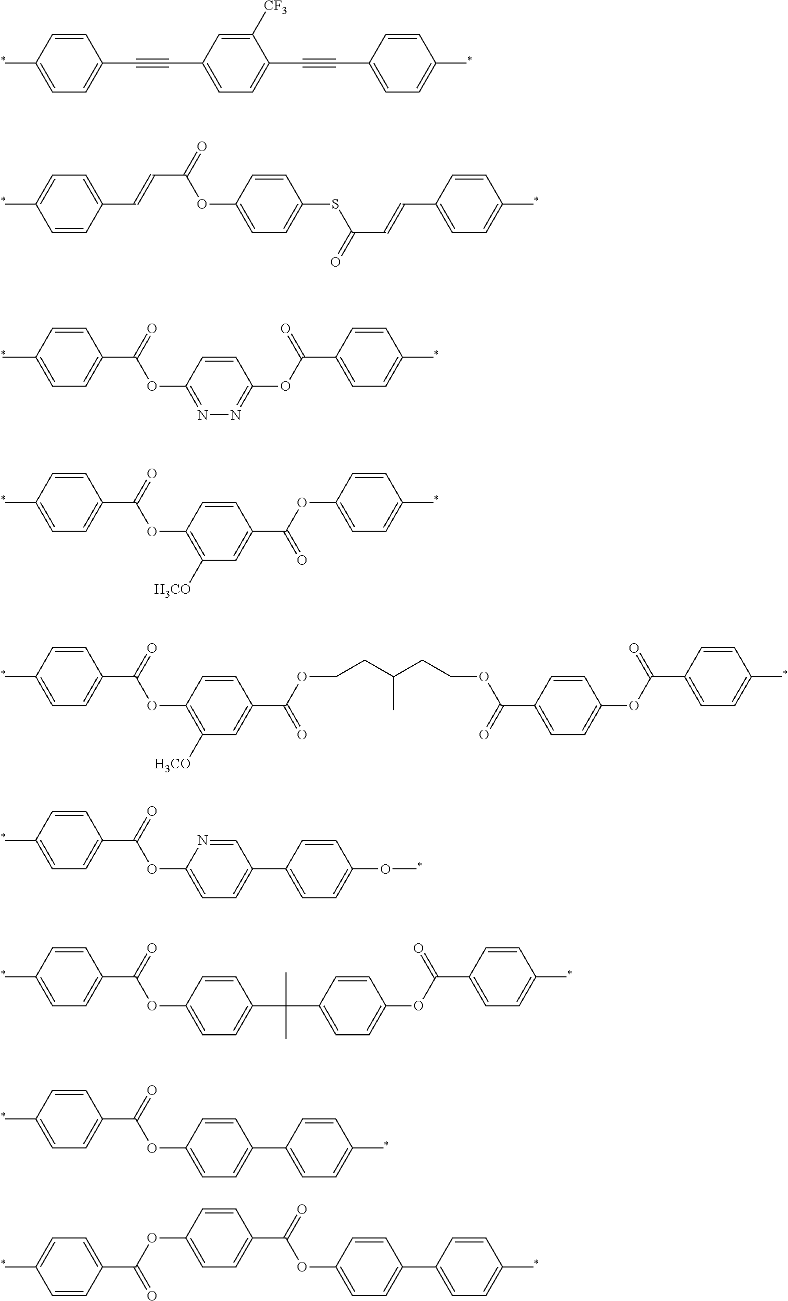

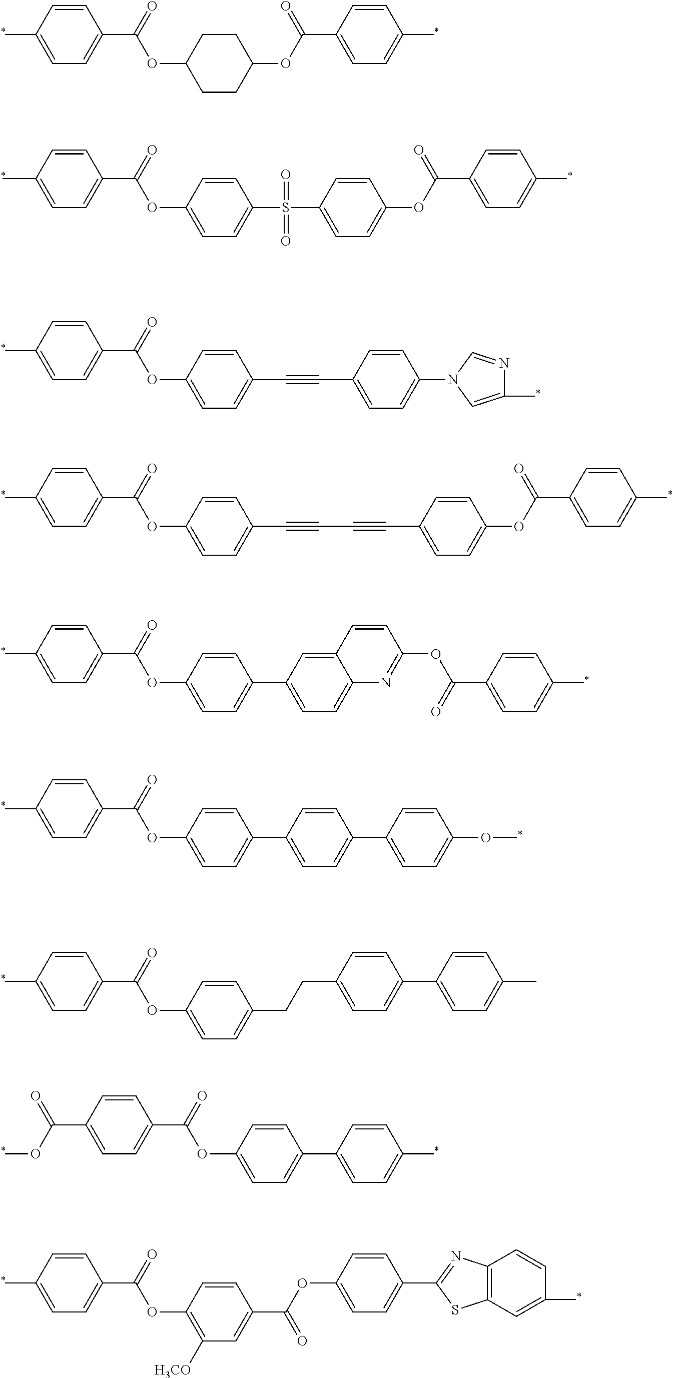

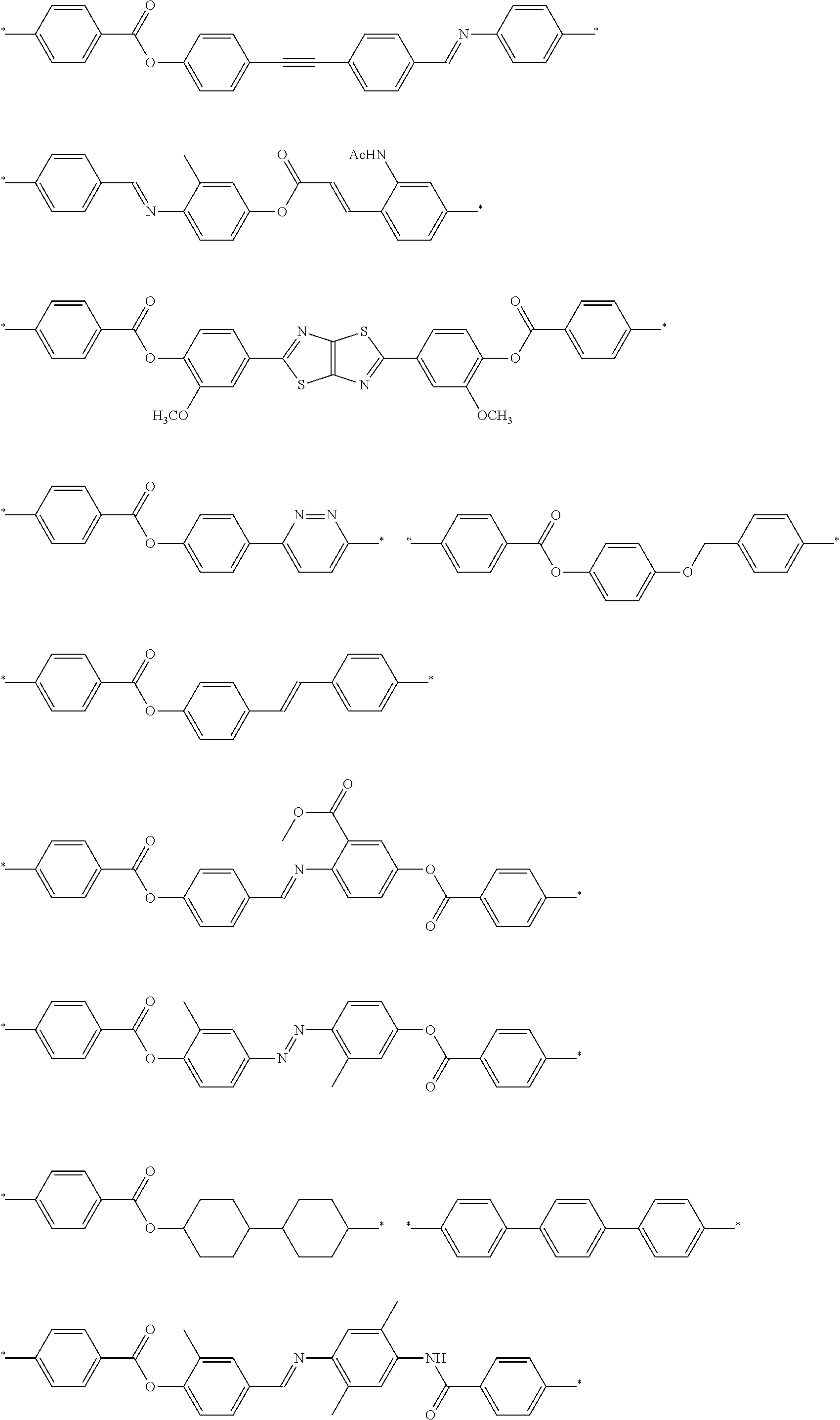

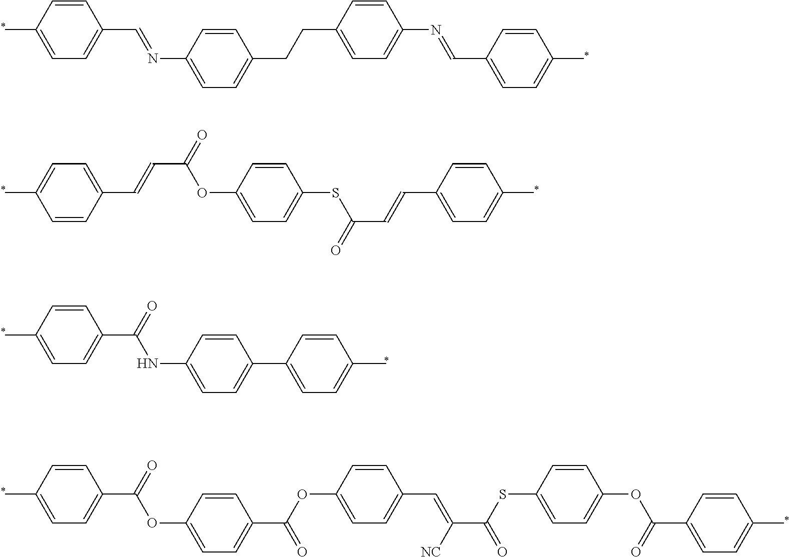 [SMILES: *c1ccc(/C=N/c2ccc(CCc3ccc(/N=C/c4ccc(*)cc4)cc3)cc2)cc1 ; *c1ccc(/C=C/C(=O)Oc2ccc(SC(=O)/C=C/c3ccc(*)cc3)cc2)cc1 ; *c1ccc(C(=O)Nc2ccc(-c3ccc(*)cc3)cc2)cc1 ; *c1ccc(C(=O)Oc2ccc(SC(=O)/C(C#N)=C/c3ccc(OC(=O)c4ccc(OC(=O)c5ccc(*)cc5)cc4)cc3)cc2)cc1]

Examples of the terminal group represented by T1 include a hydrogen atom, a halogen atom, a cyano group, a nitro group, a hydroxy group, an alkyl group having 1 to 10 carbon atoms, an alkoxy group having 1 to 10 carbon atoms, an alkylthio group having 1 to 10 carbon atoms, an alkoxycarbonyloxy group having 1 to 10 carbon atoms, an alkoxycarbonyl group (ROC(O)—: R is an alkyl group) having 1 to 10 carbon atoms, an acyloxy group having 1 to 10 carbon atoms, an acylamino group having 1 to 10 carbon atoms, an alkoxycarbonylamino group having 1 to 10 carbon atoms, a sulfonylamino group having 1 to 10 carbon atoms, a sulfamoyl group having 1 to 10 carbon atoms, a carbamoyl group having 1 to 10 carbon atoms, a sulfinyl group having 1 to 10 carbon atoms, a ureide group having 1 to 10 carbon atoms, and a (meth)acryloyloxy group-containing group. Examples of the (meth)acryloyloxy group-containing group include a group represented by -L-A (L represents a single bond or a linking group; specific examples of the linking group are the same as those of L1 and SP1, and A represents a (meth)acryloyloxy group).

For a reason that the alignment degree of the obtained liquid crystal layer is higher, T1 is preferably an alkoxy group having 1 to 10 carbon atoms, more preferably an alkoxy group having 1 to 5 carbon atoms, and still more preferably a methoxy group, these terminal groups may be further substituted with these groups or the polymerizable group described in JP201.0-244038A.

For a reason that the alignment degree of the obtained liquid crystal layer is higher, the number of atoms in the main chain of T1 is preferably 1 to 20, more preferably 1 to 15, still more preferably 1 to 10, and particularly preferably 1 to 7. In a case where the number of atoms in the main chain of T1 is 20 or less, the alignment degree of the liquid crystal layer is further improved. Here, the “main chain” in T1 means the longest molecular chain bonded to M1, and the number of hydrogen atoms is not counted as the number of atoms in the main chain of T1. For example, in a case where T1 is an n-butyl group, the number of atoms in the main chain is 4, and in a case where T1 is a sec-butyl group, the number of atoms in the main chain is 3.

For a reason that the alignment degree of the obtained liquid crystal layer is higher, a content of the repeating unit (1) is preferably 20% to 100% by mass with respect to 100% by mass of all repeating units in the high-molecular-weight liquid crystalline compound.

In the present invention, a content of each repeating unit included in the high-molecular-weight liquid crystalline compound is calculated based on a charged amount (mass) of each monomer used to obtain each repeating unit.

The high-molecular-weight liquid crystalline compound may include one kind of the repeating unit (1) alone or two or more kinds thereof. Among those, two kinds of the repeating units (1) are preferably included in the high-molecular-weight liquid crystalline compound for a reason that the alignment degree of the obtained liquid crystal layer is higher.

In a case where the high-molecular-weight liquid crystalline compound includes two kinds of the repeating units (1), for a reason that the alignment degree of the obtained liquid crystal layer is higher, it is preferable that the terminal group represented by T1 in one repeating unit (repeating unit A) is an alkoxy group and the terminal group represented by T1 in the other repeating unit (repeating unit B) is a group other than an alkoxy group.

For a reason that the alignment degree of the obtained liquid crystal layer is higher, the terminal group represented by T1 in the repeating unit B is preferably an alkoxycarbonyl group, a cyano group, or a (meth)acryloyloxy group-containing group, and more preferably an alkoxycarbonyl group or a cyano group.

For a reason that the alignment degree of the obtained liquid crystal layer is higher, a proportion (A/B) of the content of the repeating unit A in the high-molecular-weight liquid crystalline compound to the content of the repeating unit B in the high-molecular-weight liquid crystalline compound is preferably 50/50 to 95/5, more preferably 60/40 to 93/7, and still more preferably 70/30 to 90/10 in terms of a mass,

(Repeating Unit (3-2))

The high-molecular-weight liquid crystalline compound of the present, invention may further include a repeating unit (hereinafter also referred to as a “repeating unit (3-2)”) represented by Formula (3-2). Thereby, there are advantages such as improvement m a solubility of the high-molecular-weight liquid crystalline compound in a solvent and easy adjustment of the liquid crystal phase transition temperature.

The repeating unit (3-2) is different from the repeating unit (1) in that the repeating unit (3-2) has at least no mesogenic group.

In a case where the high-molecular-weight liquid crystalline compound includes the repeating unit (3-2), the high-molecular-weight liquid crystalline compound is a copolymer including the repeating unit (1) and the repeating unit (3-2) (which may also be a copolymer including the repeating units A and B), and may be any of polymers such as a block polymer, an alternating polymer, a random polymer, and a graft polymer.

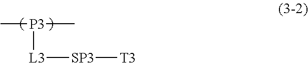

In Formula (3-2), P3 represents a main chain of the repeating unit, L3 represents a single bond or a divalent linking group, SP3 represents a spacer group, and T3 represents a terminal group.

Specific examples of P3, L3, SP3, and T3 in formula (3-2) are the same as those of P1, L1, SP1, and T1, respectively, in Formula (1).

Here, T3 in Formula (3-2) preferably has a polymerizable group from the viewpoint that the hardness of the liquid crystal layer is improved.

In a case where the repeating unit (3-2) is contained, a content thereof is preferably 0.5% to 40% by mass and more preferably 1% to 30% by mass, with respect to 100% by mass of all repeating units in the high-molecular-weight liquid crystalline compound.

The high-molecular-weight liquid crystalline compound may include one kind of repeating unit (3-2) alone, or two or more kinds thereof. In a case where the two or more kinds of the repeating units (3-2) are included, a total amount thereof is preferably within the range.

(Weight-Average Molecular Weight)

For a reason that the alignment degree of the obtained liquid crystal layer is higher, a weight-average molecular weight (Mw) of the high-molecular-weight liquid crystalline compound is preferably 1,000 to 500,000 and more preferably 2,000 to 300,000. In a case where the Mw of the high-molecular-weight liquid crystalline compound is within the range, handling of the high-molecular-weight liquid crystalline compound is easy.

In particular, from the viewpoint of suppression of cracks during application, the weight-average molecular weight (Mw) of the high-molecular-weight liquid crystalline compound is preferably 10,000 or more, and more preferably 10,000 to 300,000.

Furthermore, from the viewpoint of a temperature latitude of the alignment degree, the weight-average molecular weight (Mw) of the high-molecular-weight liquid crystalline compound is preferably less than 10,000 and more preferably 2,000 or more and less than 10,000.

Here, the weight-average molecular weight and the number-average molecular weight in the present invention are values measured by a gel permeation chromatography (GPC) method.
Solvent (eluent): N-Methylpyrrolidone
Device name: TOSOH HLC-8220GPC
Column: Three columns of TOSOH TSKgel Super AWM-H (6 mm×15 cm) connected to each other are used
Column temperature: 25° C.
Sample concentration: 0.1% by mass
Flow rate: 0.35 mL/min
Calibration curve: Calibration curve obtained from seven samples of TSK standard polystyrene Mw of 2,800,000 to 1,050 (Mw/Mn=1.03 to 1.06) manufactured by Tosoh Corporation is used

(Content)

In the present invention, a content of the liquid crystalline compound is preferably 8% to 99% by mass, and more preferably 8% to 96% by mass with respect to a total solid content (100% by mass) in the liquid crystal composition.

Here, the “total solid content in the liquid crystal composition” refers to a component excluding a solvent, and specific examples of the solid content include the liquid crystalline compound, a dichroic substance which will be described later, a polymerization initiator, and a surfactant.

(Substituent W)

The substituent W in the present specification will be described.

Examples of the substituent W include a halogen atom, an alkyl group (for example, a tert-butyl group) (including a cycloalkyl group, a bicycloalkyl group, and a tricycloalkyl group), an alkenyl group (including a cycloalkenyl group and a bicycloalkenyl group), an alkynyl group, an aryl group, a heterocyclic group, a cyano group, a hydroxy group, a nitro group, a carboxy group, an alkoxy group, an aryloxy group, a silyloxy group, a heterocyclic oxy group, an acyloxy group, a carbamoyloxy group, an alkoxycarbonyloxy group, an aryloxycarbonyloxy group, an amino group (including an anilino group), an ammonio group, an aryl amino group, an aminocarbonylamino group, an alkoxy carbonyl amino group, an aryloxycarbonylamino group, a sulfamoylamino group, an alkyl- or arylsulfonylamino group, a mercapto group, an alkylthio group, an arylthio group, a heterocyclic thio group, a sulfamoyl group, a sulfo group, an alkyl- or arylsulfinyl group, an alkyl- or arylsulfonyl group, an acyl group, an aryloxycarbonyl group, an alkoxycarbonyl group, a carbamoyl group, an aryl- or heterocyclic azo group, an imide group, a phosphine group, a phosphinyl group, a phosphinyloxy group, a phosphinylamino group, a phosphono group, a silyl group, a hydrazine group, an ureide group, a boronic acid group (—B(OH)₂), a phosphate group (—OPO(OH)₂), a sulfate group (—OSO₃H), and any of other substituents known in the art.

Furthermore, details of the substituent are described in paragraph [0023] of JP2007-234651A.

<Surfactant>

The surfactant contained in the liquid crystal composition of the embodiment of the present invention is a copolymer having a repeating unit including an alkyl fluoride group (hereinafter also referred to as a “repeating unit F”) and a repeating unit including a ring structure (hereinafter also referred to as a “repeating unit M”) and having a content of fluorine of 32% by mass or more (hereinafter also referred to as a “specific surfactant”).

Furthermore, in the present invention, the content of fluorine represents a proportion (% by mass) of a mass of fluorine atoms contained in the specific surfactant to a total mass of the specific surfactant. The content of fluorine is a value obtained by analyzing the specific surfactant by a known structural analysis method, and can be obtained by, for example, analyzing the specific surfactant by a nuclear magnetic resonance spectrum (NMR) method.

In the present invention, a Hansen solubility parameter adopts a value calculated by inputting a structural formula of a compound into HSPiP (Ver. 5.1.08). A dispersion term δd (hereinafter also simply referred to as “δd”) of the Hansen solubility parameter is a term derived from the Van der Waals force.

Furthermore, in a specific surfactant, δd and the volume are calculated by a structural formula in which a bonding moiety of each repeating unit is substituted with a hydrogen, atom, and a value averaged by the volume ratio is adopted.

High-temperature aging at 80° C. to 140° C. is required to align, a liquid crystal compound, and the viscosity of a liquid crystal composition may be decreased during the high-temperature aging, resulting in cissing failure. As a result of the investigations conducted by the present inventors, it was clarified that there is a correlation between the δd of the surfactant and the cissing failure. Specifically, the δd of the surfactant is preferably in the range of 15.5 to 17.5, and more preferably in the range of 15.8 to 17.0 from the viewpoint that the occurrence of the cissing failure can be suppressed.

(Repeating Unit F)

The repeating unit F contained in the specific surfactant is preferably a repeating unit represented by Formula (a).

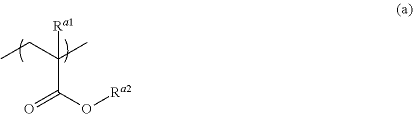

in Formula (a), R^{a1} represents a hydrogen atom or an alkyl group having 1 to 20 carbon atoms, and R^{a2} represents an alkyl group having 1 to 20 carbon, atoms or an alkenyl group having 2 to 20 carbon atoms, in which at least one carbon atom has a fluorine atom as a substituent.

The alkyl group and the alkenyl group may be linear or branched.

For a reason that the alignment defects of the obtained liquid crystal layer are further suppressed, in Formula (a), R^{a2} is preferably an alkyl group having 1 to 10 carbon atoms or an alkenylene group having 2 to 10 carbon atoms, in which at least one carbon atom has a fluorine atom as a substituent, and more preferably the alkyl group having 1 to 10 carbon atoms, in which at least one carbon atom has a fluorine atom as a substituent.

In particular, for a reason that the alignment defects of the obtained liquid crystal layer are further suppressed, it is preferable that, a half or more of the carbon atoms included in R^{a2} have a fluorine atom as a substituent.

In the present invention, the repeating unit F contained in the specific surfactant is more preferably a repeating unit, represented by formula (b),

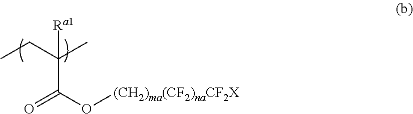

In Formula (b), R^{a1} represents a hydrogen atom or an alkyl group having 1 to 20 carbon atoms, ma and na each independently represent an integer of 0 or more, and X represent a hydrogen atom or a fluorine atom.

Here, ma is preferably an integer of 1 to 10, and na is preferably an integer of 4 to 12. R^{a1} is preferably the hydrogen atom or an alkyl group having 1 to 10 carbon atoms, more preferably the hydrogen atom or a methyl group, and particularly preferably the hydrogen atom.

Specific examples of a monomer (hereinafter also simply referred to as a “fluoroalkyl group-containing monomer”) that forms the repeating unit f contained in the specific surfactant include 2,2,2-trifluoroethyl (meth)acrylate, 2,2,3,3,3-pentafluoropropyl (meth)acrylate, 2-(perfluorobutyl)ethyl (meth)acrylate, 2-(perfluorohexyl)ethyl (meth)acrylate, 2-(perfluorooctyl)ethyl (meth)acrylate, 2-(perfluorodecyl)ethyl (meth)acrylate, 2-(perfluoro-3-methylbutyl)ethyl (meth)acrylate, 2-(perfluoro-5-methylhexyl)ethyl (meth)acrylate, 2-(perfluoro-7-methyloctyl)ethyl (meth)acrylate, 1H,1H,3H-tetrafluoropropyl (meth)acrylate, 1H,1H,5H-octafluoropentyl (meth)acrylate, 1H,1H,7H-dodecafluoroheptyl (meth)acrylate, 1H, 1H,9H-hexadecafluorononyl (meth)acrylate, 1H-1-(trifluoromethyl)trifluoroethyl (meth)acrylate, 1H, 1H,3H-hexafluorobutyl (meth)acrylate, 3-perfluorobutyl-2-hydroxypropyl (meth)acrylate, 3-perfluorohexyl-2-hydroxypropyl (meth)acrylate, 3-perfluorooctyl-2-hydroxypropyl (meth)acrylate, 3-(perfluoro-3-methylbutyl)-2-hydroxypropyl (meth)acrylate, 3-(perfluoro-5-methylhexyl)-2-hydroxypropyl (meth)acrylate, and 3-(perfluoro-7-methyloctyl)-2-hydroxypropyl (meth)acrylate.

In the present invention, a proportion of copolymerizing the fluoroalkyl group-containing monomers is preferably 0.01 to 100 moles, more preferably 0.1 to 50 mole, and still more preferably 1 to 30 moles with respect to 1 mole of the monomer that terms the repeating unit M from the viewpoint of the reactivity and the surface modification effect.

A content of the repeating unit F is preferably 20% to 99% by mole, and more preferably 55% to 74% by mole with respect to all repeating units (100% by mole) of the specific surfactant from the viewpoint of the alignment degree.

(Repeating Unit M)

The repeating unit M contained in the specific surfactant only needs to be a unit including a ring structure.

The ring structure represents, for example, at least one ring structure selected from the group consisting of an aromatic hydrocarbon group, a heterocyclic group, and an alicyclic group. From the viewpoint of suppressing alignment defects, the repeating unit M is preferably a repeating unit having two or more ring structures.

One of suitable aspects of the repeating unit M contained in the copolymer is a repeating unit represented by Formula (c).

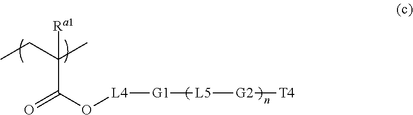

In Formula (c), R^{a1} represents a hydrogen atom or an alkyl group having 1 to 20 carbon atoms, L4 and L5 each represent a single bond or an alkylene group having 1 to 8 carbon atoms, G1 and G2 each represent a divalent cyclic group, and 14 represents a terminal group, n represents an integer of 0 to 4.

In the alkylene group represented by each of L₄ and L₅, one or more —CH₂—'s constituting the alkylene group may be substituted with at least one group selected from the group consisting of a single bond, —O—, —S—, —NR³¹—, —C(═O)—, —C(═S)—, —CR³²═CR³²—, —C≡C—, —SiR³³R³⁴—, —CR³⁵═N—N═CR³⁶—, —CR³⁷═N—, and —SO₂—, and R³¹ to R³⁷ each independently represent a hydrogen atom, a halogen atom, a cyano group, a nitro group, or a linear or branched alkyl group having 1 to 10 carbon atoms.

In addition, in a case where L represents an alkylene group, a hydrogen atom included in one or more —CH₂—'s constituting the alkylene group may be substituted with at least one group selected from the group consisting of a halogen atom, a cyano group, a nitro group, a hydroxyl group, a linear alkyl group having 1 to 10 carbon atoms, and a branched alkyl group having 1 to 10 carbon atoms.

Among those, L4 is preferably an alkyleneoxy group having 4 to 6 carbon, atoms with oxygen at a terminal, and L5 is most preferably an ester group.

The divalent cyclic groups represented by G¹ and G² each independently represent a divalent alicyclic hydrocarbon group or aromatic hydrocarbon group having 5 to 8 carbon atoms, and one or more of —CH₂—'s constituting the alicyclic hydrocarbon group may be substituted with —O—, —S—, or —NH—. Further, a plurality of the alicyclic hydrocarbon groups or the aromatic hydrocarbon groups may be single-bonded. Among these, a benzene ring is preferable.

Examples of the terminal group represented by T4 include a hydrogen atom, a halogen atom, a cyano group, a nitro group, a hydroxy group, an alkyl group having 1 to 10 carbon atoms, an alkoxy group having 1 to 10 carbon atoms, an alkylthio group having 1 to 10 carbon atoms, an alkoxycarbonyloxy group having 1 to 10 carbon atoms, an alkoxycarbonyl group (ROC(O)—: R is an alkyl group) having 1 to 10 carbon atoms, an acyloxy group having 1 to 10 carbon atoms, an acylamino group having 1 to 10 carbon a toms, an alkoxycarbonyl amino group having 1 to 10 carbon atoms, a sulfonylamino group having 1 to 10 carbon atoms, a sulfamoyl group having 1 to 10 carbon atoms, a carbamoyl group having 1 to 10 carbon atoms, a sulfinyl group having 1 to 10 carbon atoms, a ureide group having 1 to 10 carbon atoms, and a (meth)acryloyloxy group-containing group. Among these, the hydrogen atom or the cyano group is the most preferable.

One of suitable aspects of the repeating unit M may be a repeating unit represented by Formula (cc).

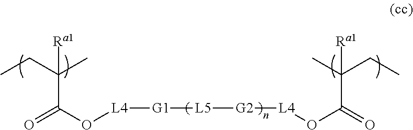

In Formula (cc), the definitions of R^{a1}, L4, L5, G1, G2, and n are each the same as those in Formula (c).

In Formula (cc), a plurality of R^{a1}'s may be the same as or different from each other, and a plurality of L4's may be the same as or different from each other.

One of suitable aspects of the repeating unit M may be a repeating unit including a group represented by Formula (ca). In the aspect, a liquid crystal layer having a more excellent alignment degree can be formed. Thus, the occurrence of cissing due to high-temperature aging during the formation of the liquid crystal layer can be further suppressed.

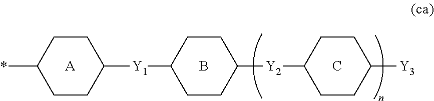

In Formula (ca), A, B, and C which are each a 6-membered ring each independently represent any of Formulae (ca1) to (ca10).

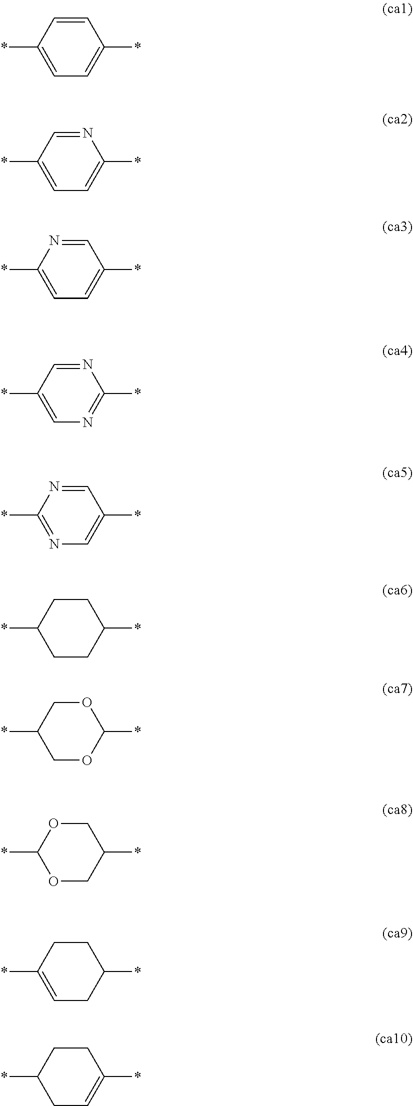

In Formulae (ca1) to (ca10), * represents a bonding position to another group, a left-side bonding site corresponds to a left-side bonding site in A, B, and C of Formula (ca), and a right-side bonding site corresponds to a right-side bonding site in A, B, and C of Formula (ca). A hydrogen atom bonded to a carbon atom that forms a ring in each of Formulae (ca1) to (ca10) may be substituted with a fluorine atom or a methyl group.

In Formula (ca), Y₁ and Y₂ each independently represent a single bond, —CH₂CH₂—, —CH₂O—, —OCH₂—, —COO—, —OCO—, —C≡C—, —CH═CH—, —CF═CF—, —(CH₂)₄—, —CH₂CH₂CH₂O—, —OCH₂CH₂CH₂—, —CH₂═CHCH₂CH₂—, or —CH₂CH₂CH═CH—. Here, in each group, a left-side bonding site corresponds to a left-side bonding site in Y₁ and Y₂, and a right-side bonding site corresponds to a right-side bonding site in Y₁ and Y₂.

Among those, Y₁ and Y₂ are each independently preferably the single bond, —CH₂CH₂—, —COO—, —OCO—, or —OC—.

In Formula (ca), Y₃ represents a hydrogen atom, a halogen atom, a cyano group, an alkyl group having 1 to 20 carbon atoms, an alkoxy group, an alkenyl group, or an alkenyloxy group.

Among those, Y₃ is preferably the hydrogen atom, a fluorine atom, the cyano group, the alkyl group having 1 to 20 carbon atoms, the alkoxy group, the alkenyl group, or the alkenyloxy group.

In Formula (ca), n represents an integer of 0 or 1.

In Formula (ca), * represents a bonding position to another group.

Specific examples of the group represented by Formula (ca) are as follows.

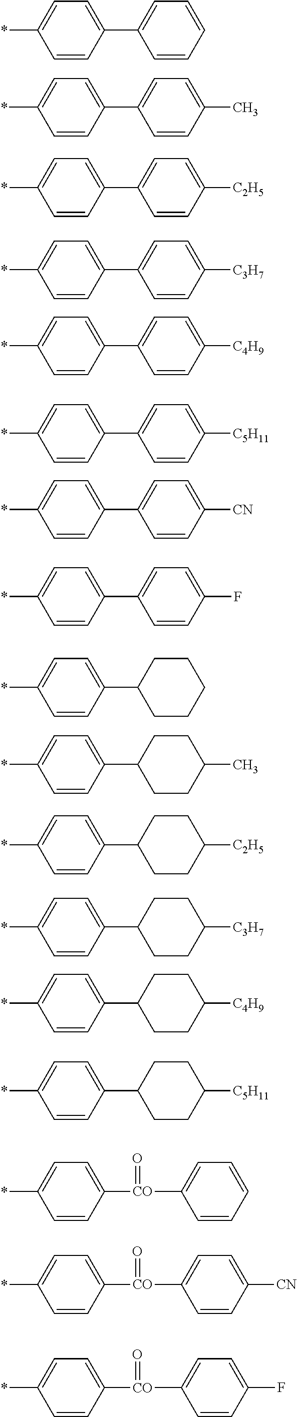

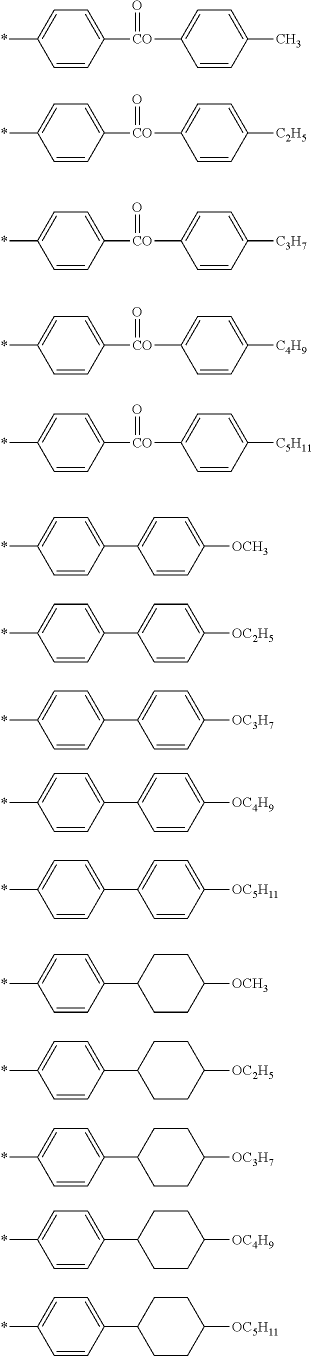

The repeating unit including the group represented by Formula (ca) is preferably a repeating unit represented by Formula (CA) from the viewpoint that a liquid crystal layer having a more excellent alignment degree can be formed.

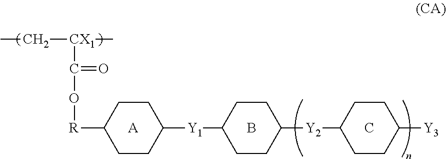

In Formula (CA), the definitions of A, B, C, Y₁, Y₂, Y₃ and n are each the same as those in Formula (ca).

In Formula (CA), X₁ represents a hydrogen atom or a methyl group.

In Formula (CA), R represents an alkylene group having 1 to 18 carbon atoms. It should be noted that —CH₂— in the alkylene group, which is not directly bonded to —C(═O)O— in Formula (CA), may be substituted with —O—. In addition, in a case where two or more —CH₂—'s in the alkylene group are substituted with —O—, —O— is not directly bonded to each other.

Specific examples of R include —(CH₂)ₜ₁—O—, —(CH₂)ₜ₂—, and —(CH₂CH₂O)ₜ₃— (t1, t2, and t3 each independently represent an integer of 1 to 18), and among these, an alkylene group having 5 to 15 carbon atoms is preferable, an alkylene group having 5 to 10 carbon atoms is more preferable, and an alkylene group having 5 to 8 carbon atoms is particularly preferable.

A content of the repeating unit M is preferably 1% to 80% by mole with respect to all repeating units (100% by mole) of the specific surfactant from the viewpoint of the alignment degree,

(Content)

For a reason that the alignment degree of the obtained liquid crystal layer is higher, a content of the specific surfactant is preferably 0.05 to 15 parts by mass, more preferably 0.08 to 10 parts by mass, and still more preferably 0.1 to 5 parts by mass with respect to 100 parts by mass of the liquid crystalline compound.

<Dichroic Substance>

The liquid crystal composition contains a dichroic substance. In the present invention, the dichroic substance means a coloring agent having an absorbance that varies depending on a direction. By incorporating the dichroic substance, the alignment degree of the liquid crystal layer is improved.

The dichroic substance is not particularly limited, and is a visible light absorbing substance (dichroic coloring agent), a luminescent substance (a fluorescent substance, a phosphorescent substance), an ultraviolet absorbing substance, an infrared absorbing substance, a nonlinear optical substance, a carbon nanotube, and an inorganic substance (for example, a quantum rod), and dichroic substances (dichroic coloring agents) known in the related art can be used.

Specific examples thereof include those described in paragraphs [0067] to [0071] of JP2013-228706A, paragraphs [0008] to [0026] of JP2013-227532A, paragraphs [0008] to [0015] of JP2013-209367A, paragraphs [0045] to [0058] of JP2013-14883A, paragraphs [0012] to [0029] of JP2013-109090A, paragraphs [0009] to [0017] of JP2013-101328A, paragraphs [0051] to [0065] of JP2013-37353A, paragraphs [0049] to [0073] of JP2012-63387A, paragraphs [0016] to [0018] of JP1999-305036A (JP-H11-305036A), paragraphs [0009] to [0011] of JP2001-133630A, paragraphs [0030] to [0169] of JP2011-215337A, paragraphs [0021] to [0075] of JP2010-106242A, paragraphs [0011] to [0025] of JP2010-215846A, paragraphs [0017] to [0069] of JP2011-048311A, paragraphs [0013] to [0133] of JP2011-213610A, paragraphs [0074] to [0246] of JP2011-237513A, paragraphs [0005] to [0051] of JP2016-006502A, paragraphs [0005] to [0041] of WO2016/060173A, paragraphs [0008] to [0062] of WO2016/136561A, paragraphs [0014] to [0013] of WO2017/154835A, paragraphs [0014] to [0033] of WO2017/154695A, paragraphs [0013] to [0037] of WO2017/195833A, paragraphs [0014] to [0034] of WO2018/164252A, and the like.

In the present invention, two or more dichroic substances may be used in combination, and for example, from the viewpoint of bringing the obtained liquid crystal layer closer to black, it is preferable to use at least one dichroic substance having a maximum absorption wavelength, in the wavelength range of 370 to 550 mu and at least one dichroic substance having a maximum absorption wavelength in the wavelength range of 500 to 700 nm in combination.

In this case, the liquid crystal layer having a dichroic substance can also be used as a polarizer.

The dichroic substance may have a crosslinkable group.

Specific examples of the crosslinkable group include a (meth)acryloyl group, an epoxy group, an oxetanyl group, and a styryl group, and among these, the (meth)acryloyl group is preferable.

(Content)

For a reason that the alignment degree of the obtained liquid crystal layer is higher, a content of the dichroic substance is preferably 1 to 400 parts by mass, more preferably 2 to 100 parts by mass, and still more preferably 5 to 30 parts by mass with respect to 100 parts by mass of the liquid crystalline compound.

<Polymerization Initiator>

The liquid crystal composition preferably includes a polymerization initiator.

The polymerization initiator is not particularly limited, but is preferably a photosensitive compound, that, is, a photopolymerization initiator.

As the photopolymerization initiator, various kinds of compounds can be used with no particular limitation. Examples of the photopolymerization initiator include the α-carbonyl compound (each of the specifications of U.S. Pat. Nos. 2,367,661A and 2,367,670A), the acyloin ether (the specification of U.S. Pat. No. 2,448,828A), the α-hydrocarbon-substituted aromatic acyloin compound (the specification of U.S. Pat. No. 2,722,512A), the polynuclear quinone compound (each of the specifications of U.S. Pat. Nos. 3,046,127A and 2,951,758A), the combination of a triarylimidazole dimer and p-aminophenyl ketone (the specification of U.S. Pat. No. 3,549,367A), the acridine and phenazine compounds (JP1985-105667A (JP-S60-105667A) and the specification of U.S. Pat. No. 4,239,850A), the oxadiazole compound (the specification of U.S. Pat. No. 4,212,970A), the o-acyloxime compounds ([0065] of JP2016-27384A), and the acyl phosphine oxide compounds (JP1988-40799B (JP-S63-40799B), JP1993-29234B (JP-H05-29234B), JP1998-95788A (JP-H10-95788A), and JP1998-29997A (JP-H10-29997A)).

A commercially available product can also be used as such a photopolymerization initiator, and examples thereof include IRGACURE-184, IRGACURE-907, IRGACURE-369, IRGACURE-651, IRGACURE-819, IRGACURE-OXE-01, and IRGACURE-OXE-02, manufactured by BASF SE.

In a case where the liquid crystal composition contains a polymerization initiator, a content of the polymerization initiator is preferably 0.01 to 30 parts by mass, and more preferably 0.1 to 15 parts by mass with respect to 100 parts by mass of a total amount of the dichroic substance and the high-molecular-weight liquid crystalline compound in the liquid crystal composition. In a case where the content of the polymerization initiator is 0.01 parts by mass or more, the durability of the liquid crystal layer is good, and in a case where the content of the polymerization initiator is 30 parts by mass or less, the alignment degree of the liquid crystal layer is better.

The polymerization initiators may be used alone or in combination of two or more kinds thereof. In a case where the two or more kinds of the polymerization initiators are included, a total amount thereof is preferably within the range.

<Solvent>

The liquid crystal composition of the embodiment of the present invention preferably contains a solvent from the viewpoint of workability and the like.

Examples of the solvent include organic solvents such as ketones (for example, acetone, 2-butanone, methyl isobutyl ketone, cyclopentanone, and cyclohexanone), ethers (for example, dioxane, tetrahydrofuran, 2-methyltetrahydrofuran, cyclopentylmethyl ether, tetrahydropyran, and dioxolane), aliphatic hydrocarbons (for example, hexane), alicyclic hydrocarbons (for example, cyclohexane), aromatic hydrocarbons (for example, benzene, toluene, xylene, and trimethylbenzene), halogenated carbons (for example, dichloromethane, trichloromethane, dichloroethane, dichlorobenzene, and chlorotoluene), esters (for example, methyl acetate, ethyl acetate, butyl acetate, and ethyl lactate), alcohols (for example, ethanol, isopropanol, butanol, cyclohexanol, isopentyl alcohol, neopentyl alcohol, diacetone alcohol, and benzyl alcohol), cellosolves (for example, methyl cellosolve, ethyl cellosolve, and 1,2-dimethoxyethane), cellosolve acetates, sulfoxides (for example, dimethyl sulfoxide), amides (for example, dimethylformamide, dimethylacetamide, N-methylpyrrolidone, and N-ethylpyrrolidone), and heterocyclic compounds (for example, pyridine), and water. These solvents may be used alone or in combination of two or more kinds thereof.

Among these solvents, ketones (in particular, cyclopentanone and cyclohexanone), ethers (in particular, tetrahydrofuran, cyclopentylmethyl ether, tetrahydropyran, and dioxolane), and amides (in particular, dimethylformamide, dimethylacetamide, N-methylpyrrolidone, and N-ethylpyrrolidone) are preferable from the viewpoint of utilizing the effect of excellent solubility.

In a case where the liquid crystal composition contains a solvent, a content of the solvent is preferably 80% to 99% by mass, more preferably 83% to 9/% by mass, and particularly preferably 85% to 95% by mass with respect to the total mass of the liquid crystal composition.

The solvents may be used alone or in combination of two or more kinds thereof. In a case where the two or more kinds of the solvents are included, a total amount thereof is preferably within the range.

[Liquid Crystal Layer]

The liquid crystal layer of an embodiment of the present invention is formed by using the above-mentioned liquid crystal composition of the embodiment of the present invention.

A method for forming the liquid crystal layer of the embodiment of the present, invention is not particularly limited, and examples thereof include a method including a step of applying the above-mentioned liquid crystal composition onto the above-mentioned photoalignment layer to form a coating film (hereinafter also referred to as a “coating film forming step”) and a step of aligning the liquid crystalline component included in the coating film (hereinafter also referred to as an “aligning step”) in this order.

Furthermore, the liquid crystalline component is a component including not only the above-mentioned liquid crystalline compound but also a liquid crystal dichroic substance in a case where the above-mentioned dichroic substance has liquid crystallinity.

<Coating Film Forming Step>

The coating film forming step is a step of forming a coating film by coating the liquid crystal composition on a photoalignment layer.

It is easier to apply a liquid crystal composition onto the photoalignment layer by using a liquid crystal composition containing the above-mentioned solvent or by using a liquid crystal composition in the form of a liquid state material such as a molten liquid by heating or the like.

Specific examples of a method for applying the liquid crystal composition include known methods such as a roll coating method, a gravure printing method, a spin coating method, a wire bar coating method, an extrusion coating method, a direct gravure coating method, a reverse gravure coating method, a die-coating method, a spray method, and an ink jet method.

<Aligning Step>

The aligning step is a step of aligning the liquid crystalline components included in the coating film. By the alignment, a liquid crystal layer can be obtained.

The aligning step may have a drying treatment. By the drying treatment, components such as a solvent can be removed from the coating film. The drying treatment may be performed by a method of leaving the coating film at room temperature for a predetermined time (for example, natural drying), or may be performed by a method of heating and/or blowing.

Here, the liquid crystalline component included in the liquid crystal composition may be aligned by the above-mentioned coating film forming step or drying treatment in some cases. For example, in an aspect in which the liquid crystal composition is prepared as a coating liquid including a solvent, a coating film having light absorbing anisotropy (that is, a light absorbing anisotropic layer) can be obtained by drying the coating film and removing the solvent from the coating film.

In a case where the drying treatment is performed at a temperature no lower than the transition temperature of the liquid crystalline component included in the coating film to a liquid crystal phase, a heating treatment which will be described later may not be carried out.

The transition temperature of the liquid crystalline component included in the coating film to the liquid crystal phase is preferably 10° C. to 250° C., and more preferably 25° C. to 190° C., from the viewpoint of manufacturing suitability and the like. In a case where the transition temperature is 10° C. or higher, a cooling treatment or the like for lowering the temperature to a temperature range in which a liquid crystal phase is exhibited is not required, which is thus preferable. Further, in a case where the transition temperature is 250° C. or lower, a high temperature is not required even in a case where the liquid crystal phase is once brought into an isotropic liquid state at a higher temperature than the temperature range in which a liquid crystal phase is exhibited, which is thus preferable since waste of thermal energy, and deformation, deterioration, or the like of a substrate can be reduced.

The aligning step preferably has a heating treatment. By the heating treatment, the liquid crystalline component included in the coating film can be aligned, and therefore, the coating film after the heating treatment can be suitably used as the light absorbing anisotropic layer.

The heating treatment is preferably performed at 10° C. to 250° C., and more preferably performed at 25° C. to 190° C., from the viewpoint of manufacturing suitability and the like. In addition, the heating time is preferably 1 to 300 seconds, and more preferably 1 to 60 seconds.

The aligning step may have a cooling treatment which is carried out after the heating treatment. The cooling treatment is a treatment for cooling the heated coating film to approximately room temperature (20° C. to 25° C.). By the cooling treatment, the alignment of the liquid crystalline component included in the coating film can be immobilized. The cooling unit is not particularly limited, and can be carried out by a known method.

A liquid crystal layer (light absorbing anisotropic layer) can be obtained by the step.

In addition, in the present aspect, examples of the method for aligning the liquid crystalline component included in the coating film include, but not limited to, the drying treatment, the heating treatment, and the like, and the method can be carried out by a known alignment treatment.

<Other Steps>

A method for forming the liquid crystal layer may have a step of curing the liquid crystal layer after the aligning step (hereinafter also referred to as a “curing step”).

For example, in a case where the liquid crystal layer has a crosslinkable group (polymerizable group), the curing step is earned out by heating and/or light irradiation (exposure). Among those, the curing step is preferably carried out by light irradiation.

Various light sources such as infrared light, visible light, and ultraviolet rays can be used as a light source for curing, but the ultraviolet rays are preferable. In addition, the ultraviolet rays may be irradiated while heating at the time of curing or the ultraviolet rays may be irradiated through a filter which transmits only a specific wavelength.

In a ease where the exposure is performed while heating, the heating temperature at the time of exposure depends on the transition temperature of the liquid crystalline component included in the liquid crystal layer to the liquid crystal phase, but is preferably 25° C. to 140° C.

In addition, the exposure may be performed in a nitrogen atmosphere. In a case where curing of the liquid crystal layer proceeds by radical polymerization, it is preferable that exposure is performed in a nitrogen atmosphere since inhibition of polymerization by oxygen is reduced.

A thickness of the liquid crystal layer is not particularly limited, but is preferably 100 to 8,000 nm, and more preferably 300 to 5,000 nm from the viewpoint of the flexibility in a case where the laminate of an embodiment of the present invention is used for a polarizing element.

[Laminate]

The laminate of the embodiment of the present invention is a laminate having at least a photoalignment layer and the above-mentioned liquid crystal layer provided on the photoalignment layer.

Furthermore, in the laminate of the embodiment of the present invention, the liquid crystalline compound included in the liquid crystal layer is immobilized in a horizontally aligned state by the above-mentioned aligning step. In addition, it is preferable that the dichroic substance included in the liquid crystal layer is also immobilized in a horizontally aligned state by the above-mentioned aligning step.

<Liquid Crystal Layer>

The liquid crystal layer included in the laminate of the embodiment of the present invention is as described above.

A content of the dichroic substance included in the liquid crystal layer is preferably 3% to 35% by mass, more preferably 8% to 30% by mass, and still more preferably 17% to 24% by mass with respect to the total solid content of the liquid crystal layer from the viewpoint that the alignment degree is more excellent.

A content of the liquid crystal compound included in the liquid crystal layer is preferably 30% to 90% by mass, and more preferably 55% to 85% by mass with, respect to the total solid content of the liquid crystal layer from the viewpoint that the alignment degree is more excellent.

A content of the specific surfactant included in the liquid crystal layer is preferably 0.1% to 10% by mass, and more preferably 0.2% to 3% by mass with respect to the total solid content of the liquid crystal layer from the viewpoint that the alignment degree is more excellent.

<Photoalignment Layer>

The photoalignment layer included in the laminate of the embodiment of the present invention is not particularly limited, and a known photoalignment layer can be used.

A material for forming the photoalignment layer is not particularly limited, but a compound having a photoaligned group is usually used. The compound may be a polymer having a repeating unit including a photoaligned group.

The photoaligned group is a functional group capable of imparting anisotropy to the film upon irradiation with light. More specifically, the photoaligned group is a group in which the molecular structure in the group can be changed upon irradiation with light (for example, linearly polarized light). Typically, the photoaligned group refers to a group which causes at least one photoreaction selected from a photoisomerization reaction, a photodimerization reaction, and a photodegradation reaction by irradiation with light (for example, linearly polarized light).

Among these photoaligned groups, the group that causes a photoisomerization reaction (a group having a photoisomerization structure) and the group that causes a photodimerization reaction (a group having a photodimerization structure) are preferable, and the group that causes photodimerization is more preferable.

The photoisomerization reaction refers to a reaction that causes stereoisomerization or structural isomerization by the action of light. As a substance that causes such a photoisomerization reaction, for example, a substance having an azobenzene structure (K. Ichimura et al., Mol. Cryst. Liq. Cryst, 298, page 221 (1997)), a substance having a hydrazono-β-keto ester structure (S. Yamamura et al., Liquid Crystals, vol. 13, No. 2, page 189 (1993)), a substance having a stilbene structure (J. G. Victor and J. M. Torkelson, Macromolecules, 20, page 2241 (1987)), a substance having a spiropyran structure (K. Ichimura et al., Chemistry Letters, page 1063 (1992); K. Ichimura et al., Thin Solid Films, vol. 235, page 101 (1993)), and the like are known.

As the group that causes a photoisomerization reaction, a group including a C═C bond or an N═N bond, which causes a photoisomerization reaction, is preferable, and examples of such a group include a group having an azobenzene structure (skeleton), a group having a hydrazono-β-keto ester structure (skeleton), a group having a stilbene structure (skeleton), and a group having a spiropyran structure (skeleton).

The photodimerization reaction refers to a reaction in which an addition reaction occurs between, two groups by the action of light, whereby a ring structure is typically formed. As a substance that, cause such photodimerization, a substance having a cinnamic acid structure (M. Schadt et al., J. Appl. Phys., Vol. 31, No. 7, page 2155 (1992)), a substance having a coumarin structure (M. Schadt et al., Nature., Vol. 381, page 212 (1996)), a substance having a chalcone structure (Toshihiro Ogawa et al., Pre-Text of Liquid Crystal Discussion Meeting, 2AB03 (1997)), a substance having a benzophenone structure (Y. K. Jang et al., SID Int. Symposium Digest, P-53 (1997)), and the like are known.

Examples of the group that causes a photodimerization reaction include a group having a cinnamic acid (cinnamoyl) structure (skeleton), a group having a coumarin structure (skeleton), a group having a chalcone structure (skeleton), a group having a benzophenone structure (skeleton), and a group having an anthracene structure (skeleton). Among these groups, the group having a cinnamoyl structure and the group having a coumarin structure are preferable, and the group having a cinnamoyl structure is more preferable.

In particular, in a case where the photoalignment layer contains a compound having a photoaligned group and the photoaligned group is the group having a cinnamoyl structure, the generation of cissing due to high-temperature aging during the formation of the liquid crystal layer of the embodiment of the present invention can be further suppressed.

Moreover, the compound having a photoaligned group may further have a crosslinkable group.

As the crosslinkable group, a thermally crosslinkable group that causes a curing reaction by the action of heat, or a photocrosslinkable group that causes a curing reaction by the action of light is preferable, and the crosslinkable group may be a crosslinkable group having both the thermally crosslinkable group and the photocrosslinkable group.

Examples of the crosslinkable group include at least one selected from the group consisting of an epoxy group, an oxetanyl group, a group represented by —NH—CH₂—O—R (R represents a hydrogen atom or an alkyl group having 1 to 20 carbon atoms), a group having an ethylenically unsaturated double bond, and a blocked isocyanate group. Among these, the epoxy group, the oxetanyl group, and the group having an ethylenically unsaturated double bond are preferable.

Furthermore, the 3-membered cyclic ether group is also ret erred to as an epoxy group, and the 4-membered cyclic ether group is also referred to as an oxetanyl group.

In addition, specific examples of the group having an ethylenically unsaturated double bond include a vinyl group, an allyl group, a styryl group, an acryloyl group, and a methacryloyl group, and the acryloyl group or the methacryloyl group is preferable.

As one of the suitable aspects of the photoalignment layer, a photoalignment layer formed with the composition for forming a photoalignment layer, including a polymer A having a repeating unit a1 including a cinnamate group and a low-molecular-weight compound B having a cinnamate group and having a lower molecular weight than that of the polymer A, may be mentioned.

Here, in the present specification, the cinnamate group is referred to as a group having a cinnamic acid structure including cinnamic acid or a derivative thereof as a basic skeleton, in which the group is represented by Formula (I) or formula (II).

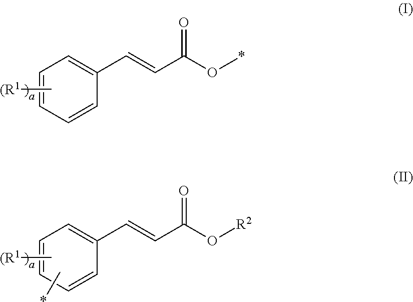

In Formula, R¹ represents a hydrogen atom or a monovalent organic group, and R² represents a monovalent organic group. In Formula (I), a represents an integer of 0 to 5, and in Formula (II), a represents 0 to 4. In a case where a is 2 or more, a plurality of R¹'s may be the same as or different from each other. * represents a bond.

The polymer A is not particularly limited as long as it is a polymer having a repeating unit a1 including a cinnamate group, and a polymer known in the related art can be used.

A weight-average molecular weight of the polymer A is preferably 1,000 to 500,000, more preferably 2,000 to 300,000, and still more preferably 3,000 to 200,000.

Here, the weight-average molecular weight is defined as a value expressed in terms of polystyrene (PS), measured by means of gel permeation chromatography (GPC), and the measurement by means of GPC in the present invention can be made using HLC-8220 GPC (manufactured by Tosoh Corporation), and TSKgel Super HZM-H, HZ4000, and HZ2000 as columns.

Examples of the repeating unit a1 including a cinnamate group, contained in the polymer A, include repeating units represented by Formulae (A1) to (A4).

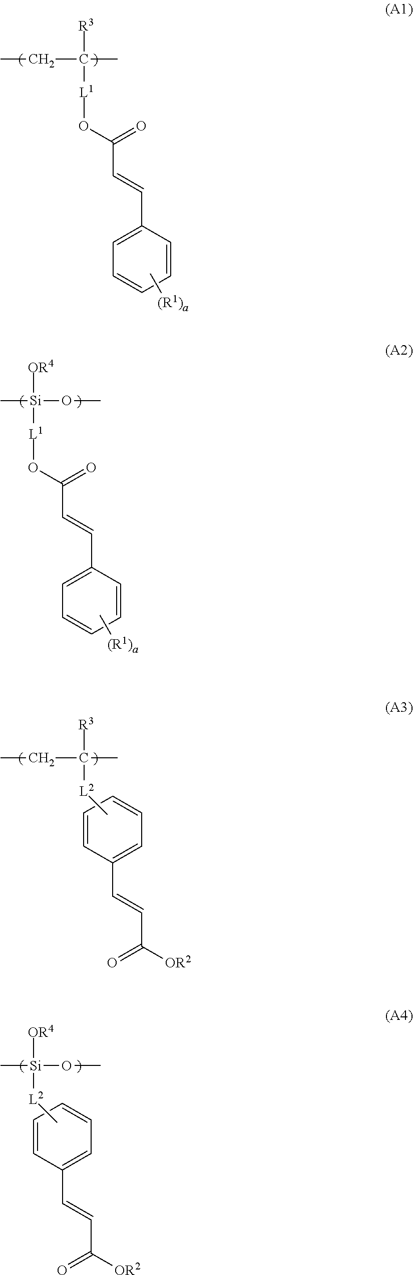

Here, in Formulae (A1) and (A3), R³ represents a hydrogen atom or a methyl group, and in Formulae (A2) and (A4), R⁴ represents an alkyl group having 1 to 6 carbon atoms.

In Formulae (A1) and (A2), L¹ represents a single bond or a divalent linking group, a represents an integer from 0 to 5, and R⁵ represents a hydrogen atom or a monovalent organic group.

In Formulae (A3) and (A4), L² represents a divalent linking group and R² represents a monovalent organic group.

In addition, specific examples of L¹ include —CO—O-Ph-, —CO—O-Ph-Ph-, —CO—O—(CH₂)ₙ—, —CO—O—(CH₂)ₙ-Cy-, and —(CH₂)ₙ-Cy-. Here, Ph represents a divalent benzene ring which may have a substituent (for example, a phenylene group), Cy represents a divalent cyclohexane ring which may have a substituent (for example, a cyclohexane-1,4-diyl group), and n represents an integer of 1 to 4.

In addition, specific examples of L² include —O—CO— and —O—CO—(CH₂)ₘ—O—. Here, m represents an integer of 1 to 6.

In addition, examples of the monovalent organic group of R¹ include a chain or cyclic alkyl group having 1 to 20 carbon atoms, an alkoxy group having 1 to 20 carbon atoms, and an aryl group having 6 to 20 carbon atoms, which may have a substituent.

Furthermore, examples of the monovalent organic group of R² include a chain, oi cyclic alkyl group having 1 to 20 carbon atoms, and an aryl group having 6 to 20 carbon atoms, which may have a substituent.

Moreover, a is preferably 1 and R¹ is preferably present in the para position.

In addition, examples of the substituent which may be contained in Ph, Cy, and the aryl group, each mentioned above, may have include an alkyl group, an alkoxy group, a hydroxy group, a carboxy group, and an amino group.

From the viewpoints that the alignment of the liquid crystal layer is further improved and the adhesiveness of the liquid crystal layer is further improved, it is preferable that the polymer A further has a repeating unit a2 including a crosslinkable group.

The definition and suitable aspects of the crosslinkable group are as described above.

Among those, as the repeating unit a2 including a crosslinkable group, a repeating unit having an epoxy group, an oxetanyl group, or a group having an ethylenically unsaturated double bond is preferable.

The following repeating units can be exemplified as preferred specific examples of the repeating unit, having an epoxy group, an oxetanyl group, or a group having an ethylenically unsaturated double bond. Furthermore, R³ and R⁴ have the same definitions as R³ and R⁴, respectively, in Formulae (A1) and (A2).

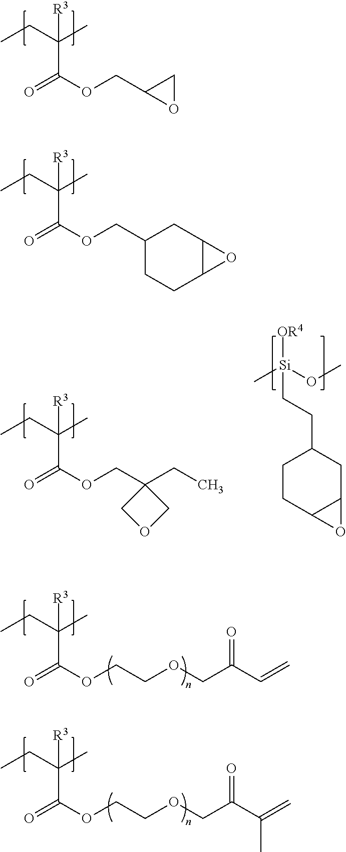

The polymer A may have another repeating unit other than the repeating unit a1 and the repeating unit a2, each mentioned above.

Examples of a monomer forming such another other repeating unit include an acrylic acid ester compound, a methacrylic acid ester compound, a maleimide compound, an acrylamide compound, acrylonitrile, maleic acid anhydride, a styrene compound, and a vinyl compound.

A content of the polymer A in the composition for forming a photoalignment layer is preferably 0.1 to 50 parts by mass, and more preferably 0.5 to 10 parts by mass with respect to 100 parts by mass of the solvent in a case where an organic solvent which will be described later is included.

The low-molecular-weight compound B is a compound having a cinnamate group and having a lower molecular weight than the polymer A. By using the low-molecular-weight compound B, the alignment of the produced photoalignment layer is better.

For a reason that the alignment of the photoalignment layer is further improved, a molecular weight of the low-molecular-weight compound B is preferably 200 to 500, and more preferably 200 to 400.

Examples of the low-molecular-weight compound B include a compound represented by Formula (B1).

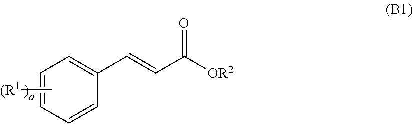

In Formula (B1), a represents an integer from 0 to 5, R¹ represents a hydrogen atom oi a monovalent organic group, and R² represents a monovalent organic group. In a case where a is 2 or more, a plurality of R¹'s may be the same as or different from each other.

In addition, examples of the monovalent organic group of R¹ include a chain or cyclic alkyl group having 1 to 20 carbon atoms, an alkoxy group having 1 to 20 carbon atoms, and an aryl group having 6 to 20 carbon atoms, which may have a substituent, and among these, the alkoxy group having 1 to 20 carbon atoms is preferable, an alkoxy group having 1 to 6 carbon atoms is more preferable, and a methoxy group or an ethoxy group is still more preferable.

Furthermore, examples of the monovalent organic group of R include a chain or cyclic alkyl group having 1 to 20 carbon atoms and an aryl group having 6 to 20 carbon atoms, which may have a substituent, and among these, the chain alkyl group having 1 to 20 carbon atoms is preferable, and a branched alkyl group having 1 to 10 carbon atoms is more preferable.

Moreover, a is preferably 1 and R¹ is preferably present in the para position.

In addition, examples of the substituent which may be contained in the above-mentioned aryl group may have include an alkyl group, an alkoxy group, a hydroxy group, a carboxy group, and an amino group.

A content of the low-molecular-weight compound B in the composition for forming a photoalignment layer is preferably 10% to 500% by mass, and more preferably 30% to 300% by mass with, respect to a mass of the constitutional unit a1 of the polymer A.

For a reason that the alignment is further improved, the composition for forming a photoalignment layer preferably includes a crosslinking agent C having a crosslinkable group, in addition to the polymer A having a constitutional unit a2 including a crosslinkable group.

A molecular weight of the crosslinking agent C is preferably 1,000 or less, and more preferably 100 to 500.

Examples of the crosslinking agent C include a compound having two or more epoxy groups or oxetanyl groups in the molecule, a blocked isocyanate compound (a compound having a protected isocyanato group), and an alkoxymethyl group-containing compound.

Among those, the compound having two or more epoxy groups or oxetanyl groups in the molecule, or the blocked isocyanate compound is preferable.

In a case where the composition for forming a photoalignment layer includes the crosslinking agent C, a content of the crosslinking agent C is preferably 1 to 1,000 parts by mass, and more preferably 10 to 500 parts by mass with respect to 100 parts by mass of the constitutional unit a1 of the polymer A.

From the viewpoint of workability for producing a photoalignment layer, it is preferable that the composition for forming a photoalignment layer includes a solvent. Examples of the solvent include water and an organic solvent.

Specific examples of the organic solvent include ketones (for example, acetone, 2-butanone, methyl isobutyl ketone, cyclohexanone, and cyclopentanone), ethers (for example, dioxane and tetrahydrofuran), aliphatic hydrocarbons (for example, hexane), alicyclic hydrocarbons (for example, cyclohexane), aromatic hydrocarbons (for example, toluene, xylene, and trimethylbenzene), halogenated carbons (for example, dichloromethane, dichloroethane, dichlorobenzene, and chlorotoluene), esters (for example, methyl acetate, ethyl acetate, and butyl acetate), alcohols (for example, ethanol, isopropanol, butanol, and cyclohexanol), cellosolves (for example, methyl cellosolve and ethyl cellosolve), cellosolve acetates, sulfoxides (for example, dimethyl sulfoxide), and amides (for example, dimethylformamide and dimethylacetamide). These solvents may be used alone or in combination of two or more kinds thereof.

The composition for forming a photoalignment layer may include components other than the above-mentioned components, and examples of the components include a crosslinking catalyst, an adhesion improver, a leveling agent, a surfactant, and a plasticizer.

<Method for Forming Photoalignment Layer>

A method for forming the photoalignment layer is not particularly limited, and for example, the photoalignment layer can be produced by an applying step of applying the above-mentioned composition for forming the photoalignment layer onto a surface of a support, and a light irradiating step of irradiating the coating film of the composition for forming a photoalignment layer with polarized light or with non-polarized light from an oblique direction with respect to the coating film surface.

(Support) Examples of the support include a glass substrate and a polymer film.

As the material for the polymer film include cellulose-based polymers; acryl-based polymers; thermoplastic norbornene-based polymers; polycarbonate-based polymers, polyester-based polymers such as polyethylene terephthalate and polyethylene naphthalate, styrene-based polymers such as polystyrene and an acrylonitrile-styrene copolymer (AS resin), polyolefin-based polymers such as polyethylene, polypropylene, and an ethylene-propylene copolymer; vinyl chloride-based polymers; amide-based polymers such as a nylon and an aromatic polyamide; imide-based polymers; sulfone-based polymers; polyether sulfone-based polymers; polyether ether ketone-based polymers; polyphenylene sulfide-based polymers, vinylidene chloride-based polymers; vinyl alcohol-based polymers; vinyl butyral-based polymers; arylate-based polymers; polyoxymethylene-based polymers; and epoxy-based polymers; or polymers obtained by mixing these polymers.

A thickness of the support is not particularly limited, but is preferably 5 to 60 μm, and more preferably 5 to 30 μm.

<Alignment Layer>

A case where the photoalignment layer is included as the laminate of the embodiment of the present invention has been described, but an alignment layer (hereinafter also referred to as “another alignment layer”) other than the photoalignment layer may be used instead of the photoalignment layer in order to align the liquid crystal compound.

Examples of a method for forming such another alignment layer include methods such as a rubbing treatment of an organic compound (preferably, a polymer) on a film surface, oblique vapor deposition of an inorganic compound, formation of a layer having microgrooves, and accumulation of an organic compound (for example, ω-tricosanoic acid, dioctadecyl methylammonium chloride, methyl stearate, and the like) by a Langmuir-Blodgett method (LB film). Moreover, an alignment, layer in which an alignment function is generated by application of an electric field or application of a magnetic field is also known.

Among those, as such another alignment layer, an alignment layer (rubbing-treated alignment layer) formed by performing a rubbing treatment is preferable from the viewpoint of easy control of a pretilt angle of the alignment layer.

Polymer materials used for the rubbing-treated alignment layer are described in many documents, and a large number of commercially available products can be acquired. In the present invention, a polyvinyl alcohol or a polyimide, and derivatives thereof are preferably used. With regard to the alignment layer, reference can be made to the descriptions on page 43 line 24 to page 49, line 8 of WO01/88574A1. A thickness of the rubbing-heated alignment layer is preferably 0.01 to 10 μm, and more preferably 0.01 to 2 μm.

<λ/4 Plate>

In a case where the above-mentioned liquid crystal layer functions as a polarizer, it is preferable that the laminate of the embodiment of the present invention has a λ/4 plate. Here, the “λ/4 plate” is a plate having a λ/4 function, specifically, a plate having a function of converting a linearly polarized light at a certain specific wavelength into a circularly polarized light (or converting a circularly polarized light to a linearly polarized light).

For example, specific examples of an aspect in which the λ/4 plate has a monolayer structure include a stretched polymer film and a phase difference film having an optimally anisotropic layer having a λ/4 function provided on a support, and specific examples of an aspect in which the λ/4 plate has a multilayer structure include a broadband λ/4 plate obtained by laminating a λ/4 plate and a λ/2 plate.

The λ/4 plate and the liquid crystal layer may be provided to be in contact with each other, or another laver may be provided between the λ/4 plate and the liquid crystal layer. Examples of such a layer include a pressure sensitive adhesive layer or adhesive layer for ensuring adhesiveness.

<Barrier Layer>

The laminate of the embodiment of the present invention preferably has a barrier layer together with a liquid crystal layer.

Here, the harrier layer is also called a gas shielding layer (oxygen shielding layer), and has a function of protecting the liquid crystal layer from a gas such as oxygen in the air, moisture, compounds included in an adjacent layer, and the like.

With regard to the barrier layer, reference can be made to, for example, the descriptions in paragraphs [0014] to [0054] of JP20.14-159124A, paragraphs [0042] to [0075] of JP2017-121721A, paragraphs [0045] to [0054] of JP2017-115076A, paragraphs [0010] to [0061] of JP2012-213938A, or paragraphs [0021] to [0031] of JP2005-169994A.

<Cured Layer>

In the laminate of the embodiment of the present invention, in a case where the above-mentioned liquid crystal layer has a dichroic substance and is used for the purpose of antireflection as a circularly polarizing plate, internal reflection due to a high refractive index of the liquid crystal layer may be problematic. In that case, a cured layer which will be described below is preferably present. The cured layer is a layer arranged so as to be in contact with the liquid crystal layer, is formed from a composition containing a compound having a crosslinkable group, and has an in-plane average refractive index from 1.55 to 1.70 at a wavelength of 550 nm. The cured layer is preferably a refractive index-adjusting layer for performing a so-called index matching.

An in-plane average refractive index of the refractive index-adjusting layer may be within the range, but is preferably 1.58 to 1.70 and more preferably 1.60 to 1.70.

A thickness of the refractive index-adjusting layer is not particularly limited, but is preferably 0.01 to 2.00 μm, more preferably 0.01 to 0.80 μm, and still more preferably 0.01 to 0.15 μm from, the viewpoint of reduction in the thickness.

A type of a component constituting the refractive index-adjusting layer is not particularly limited as long as the component contains a compound having a crosslinkable group. The hardness in the layer can be ensured by the presence of the crosslinkable group. A compound cured by light or heat, for example, a polymerizable compound having a (meth)acryloyl group or an epoxy group is preferable. Moreover, from the viewpoint that a high in-plane average refractive index can be obtained, a polymerizable liquid crystalline compound is also preferable. Furthermore, the polymerizable liquid crystalline compound can control the anisotropy of the refractive index in the plane, and thus has a high potential for optimizing the refractive index with the liquid crystal layer having the refractive index anisotropy in the plane.

The refractive index-adjusting layer may include particles together with the compound having a crosslinkable group. Examples of the particles include organic particles, inorganic particles, and organic-inorganic composite particles including an organic component and an inorganic component.

Examples of the organic particles include styrene resin particles, styrene-divinylbenzene copolymer particles, acrylic resin particles, methacrylic resin particles, styrene-acryl copolymer particles, styrene-methacryl copolymer particles, melamine resin particles, and resin particles including two or more kinds thereof.

Examples of a component constituting the inorganic particles include a metal oxide, a metal nitride, a metal oxynitride, and a metal simple substance. Examples of a metallic atom, included in the metal oxide, metal nitride, metal oxynitride, and metal simple substance include a titanium atom, a silicon atom, an aluminum atom, a cobalt atom, and a zirconium atom. Specific examples of the inorganic particles include inorganic oxide particles such as alumina particles, hydrated alumina particles, silica particles, zirconia particles, and a clay mineral (for example, smectite). From the viewpoint that a high refractive index can be obtained, zirconia particles are preferable.

An average particle diameter of the particles is preferably 1 to 300 nm, and more preferably 10 to 200 nm. in a case where the average particle diameter is within the range, a cured product (transparent resin layer) having excellent dispersibility of the particles and superior high-temperature durability, moisture-heat resistance, and transparency can be obtained.

Here, the average particle diameter of the particles can be obtained from a photograph obtained by observation with a transmission electron microscope (IEM) or a scanning electron microscope (SEM). Specifically, the projected area of the particle is obtained, and the corresponding circle-equivalent diameter (a diameter of a circle) is taken as the average particle diameter of the particles. Moreover, the average particle diameter in the present invention is an arithmetic mean value of circle-equivalent diameters obtained tor 100 particles. The particles may have any shape such as a spherical shape, a needle shape, a fiber (fiber shape), a columnar shape, and a plate shape.

A content of the particles in the refractive index-adjusting layer is not particularly limited, but is preferably 1% to 50% by mass and more preferably 1% to 30% by mass, with respect to the total mass of the refractive index-adjusting layer, from the viewpoint that the in-plane average refractive index of the refractive index-adjusting layer is easily adjusted.

A method for forming the refractive index-adjusting layer is not particularly limited, but examples thereof include a method in which a composition for forming a refractive index-adjusting layer is applied onto a liquid crystal layer, and the coating film is subjected to a curing treatment, as necessary.

The composition for forming a refractive index-adjusting layer includes components which can constitute the refractive index-adjusting layer, and examples of the components include a resin, a monomer, and particles. Examples of the resin and the particles are as described above.

Examples of the monomer include a photocurable compound and a thermosetting compound (for example, a thermosetting resin). As the monomer, a monofunctional polymerizable compound including one polymerizable group in one molecule, and a polyfunctional polymerizable compound including the same or different two or more polymerizable groups in one molecule are preferable. The polymerizable compound may be a monomer or a multimer such as an oligomer or a prepolymer.

Examples of the polymerizable group include a radically polymerizable group and a cationically polymerizable group, and a radically polymerizable group is preferable. Examples of the radically polymerizable group include an ethylenically unsaturated bond group. Examples of the cationically polymerizable group include an epoxy group and an oxetane group.

The composition for forming a refractive index-adjusting layer may include at least one of a surfactant (interface modifier), a polymerization initiator, or a solvent. Examples of these components include the compounds exemplified as the components which may be included in the liquid crystal composition.

A method for applying the composition for forming a refractive index-adjusting layer is not particularly limited, and examples thereof include the above-mentioned method for applying the liquid crystal composition.

After the composition for forming a refractive index-adjusting layer is applied, as necessary, the coating film may be subjected to a drying treatment.

Furthermore, in a case where the composition for forming a refractive index-adjusting layer includes a curable compound such as a monomer, after the composition for forming a refractive index-adjusting layer is applied, the coating film may be subjected to a curing treatment.

Examples of the curing treatment include a photocuring treatment and a thermosetting treatment, and optimal conditions are selected according to the material used.

In a case where a polymerizable liquid crystalline compound is used tor forming a refractive index-adjusting layer, the compound is not particularly limited.

In general, the liquid crystalline compound can be classified into a rod-like type and a disk-like type according to the shape thereof. Furthermore, each liquid crystalline compound may be either of a low-molecular-weight type or of a high-molecular type. In general, the high-molecular-weight type compound indicates a compound having a degree of polymerization of 100 or more (Polymer Physics-Phase Transition Dynamics, written by Masao DOI, page 2, Iwanami Shoten, Publishers, 1992).

In the present invention, any liquid crystalline compound can be used, but a rod-like liquid crystalline compound (hereinafter also simply referred to as “CLC”) or a discotic liquid crystalline compound (hereinafter also simply referred to as “DLC”) is preferably used, and the rod-like liquid crystalline compound is more preferably used. Moreover, two or more kinds of rod-like liquid crystalline compounds, two or more kinds of disk-like liquid crystalline compounds, or a mixture of the rod-like liquid crystalline compound and the disk-like liquid crystalline compound may be used.

In a case where the liquid crystalline compound is used for forming the refractive index-adjusting layer, it is preferable to use a liquid crystalline compound having a polymerizable group (polymerizable liquid crystalline compound) for immobilization of the liquid crystalline compound, and it is more preferable that the liquid crystalline compound has two or more polymerizable groups in the molecule. Moreover, in a case where the liquid crystalline compound is a mixture of two or more kinds thereof, it is preferable that at least one kind of the liquid crystalline compounds has two or more polymerizable groups in one molecule. Furthermore, after the liquid crystalline compound is immobilized by polymerization, it is no longer necessary to exhibit liquid crystallinity.

In addition, a type of the polymerizable group is not particularly limited, and the polymerizable group is preferably a functional group capable of an addition polymerization reaction, and is also preferably a polymerizable ethylenically unsaturated group or a ring polymerizable group. More specifically, preferred examples of the polymerizable group include a (meth)acryloyl group, a vinyl group, a styryl group, and an allyl group, and the (meth)acryloyl group is more preferable. Moreover, the (meth)acryloyl group is a notation meaning a methacryloyl group or an acryloyl group.

As the rod-like liquid crystalline compound, for example, the compounds described in claim 1 of JP1999-513019A (JP-H11-513019A) or paragraphs [0026] to [0098] of JP2005-289980A can be preferably used, and as the discotic liquid crystalline compound, for example, the compounds described in paragraphs [0020] to [0067] of JP2007-108732A or paragraphs [0013] to [0108] of JP2010-244038A can be preferably used, but the present invention is not limited to these examples.

Specific examples of other components included in the composition for forming a refractive index-adjusting layer include the polymerization initiator, the surfactant, and the solvent, each described for the above-mentioned liquid crystal composition.

<Method for Forming Refractive Index-Adjusting Layer>

A method for forming a refractive index-adjusting layer using the composition for forming a refractive index-adjusting layer, including the liquid crystalline compound, is not particularly limited, and examples thereof include a method including a step (hereinafter also referred to as a “coating film forming step”) of applying the above-mentioned composition for forming a refractive index-adjusting layer onto the photoalignment layer or the liquid crystal layer according to the layer configuration to form a coating film, and a step (hereinafter also referred to as an “aligning step”) of aligning liquid crystalline components included in the coating film, in this order.

Here, examples of the coating film forming step and the aligning step include the same steps as those described for the above-mentioned method for forming a liquid crystal layer.

<Pressure Sensitive Adhesive Layer>

From the viewpoint of adhering the above-mentioned λ/4 plate, the laminate of the embodiment of the present invention may have a pressure sensitive adhesive layer on a surface to which the λ/4 plate is bonded.

Examples of the pressure sensitive adhesive included in the pressure sensitive adhesive layer include a rubber-based pressure sensitive adhesive, an acryl-based pressure sensitive adhesive, a silicone-based pressure sensitive adhesive, a urethane-based pressure sensitive adhesive, a vinylalkyl ether-based pressure sensitive adhesive, a polyvinyl alcohol-based pressure sensitive adhesive, a polyvinylpyrrolidone-based pressure sensitive adhesive, a polyacrylamide-based pressure sensitive adhesive, and a cellulose-based pressure sensitive adhesive.

Among those, the acryl-based pressure sensitive adhesive (adhesive that is sensitive to pressure) is preferable from the viewpoints of transparency, weather fastness, heat resistance, and the like.

The pressure sensitive adhesive layer can be formed, for example, by a method in which a solution of the pressure sensitive adhesive is applied onto a release sheet and dried, and then the resultant is transferred to a surface of a transparent resin layer; a method in which a solution of the pressure sensitive adhesive is directly applied onto a surface of a transparent resin layer and dried; or the like.

For example, the solution of the pressure sensitive adhesive is prepared as a solution of about 10% to 40% by mass in which the pressure sensitive adhesive is dissolved or dispersed in a solvent such as toluene or ethyl acetate.

As a coating method, a roll coating method such as reverse coating and gravure coating, a spin coating method, a screen coating method, a fountain coating method, a dipping method, a spray method, and the like can be employed.

In addition, examples of a constituent material of the release sheet include appropriate thin leaf-like materials, for example, a film of a synthetic resin such as polyethylene, polypropylene, and polyethylene terephthalate; a rubber sheet; paper, a fabric, a non-woven fabric; a net; a foam sheet; and a metal foil.

In the present invention, a thickness of any pressure sensitive adhesive layer is not particularly limited, but is preferably 3 μm to 50 μm, more preferably 4 μm to 40 μm, and still more preferably 5 μm to 30 μm.

<Adhesive Layer>

The adhesive layer in the present invention exhibits adhesiveness by performing drying or a reaction after adhesion.

A polyvinyl alcohol-based adhesive (PVA-based adhesive) exhibits adhesiveness by being dried, and thus enables the adhesion between materials.

Specific examples of a curable adhesive which exhibits adhesiveness by being reacted include an active energy ray curing type adhesive such as a (meth)acrylate-based adhesive, and a cationic polymerization curing type adhesive. Moreover, the (meth)acrylate means acrylate and/or methacrylate. Examples of a curable component in the (meth)acrylate-based adhesive include a compound having a (meth)acryloyl group and a compound having a vinyl group.

Furthermore, a compound having an epoxy group or an oxetanyl group can also be used as the cationic polymerization-curable adhesive. The compound having an epoxy group is not particularly limited as long as it has at least two epoxy groups in the molecule, and various curable epoxy compounds generally known can be used. Preferred examples of the epoxy compound include a compound (aromatic epoxy compound) having at least two epoxy groups and at least one aromatic ring in the molecule and a compound (alicyclic epoxy compound) having at least two epoxy groups in the molecule, at least one of which is formed between two adjacent carbon atoms constituting an alicyclic ring.

<Uses>

The laminate of the embodiment of the present invention can be used as a polarizing element (polarizing plate), and specifically as, for example, a linearly polarizing plate or a circularly polarizing plate.

In a case where the laminate of the embodiment of the present invention does not have an optically anisotropic layer such as a λ/4 plate, the laminate can be used as the linearly polarizing plate.

On the other hand, in a case where the laminate of the embodiment of the present invention has the λ/4 plate, the laminate can be used as the circularly polarizing plate.

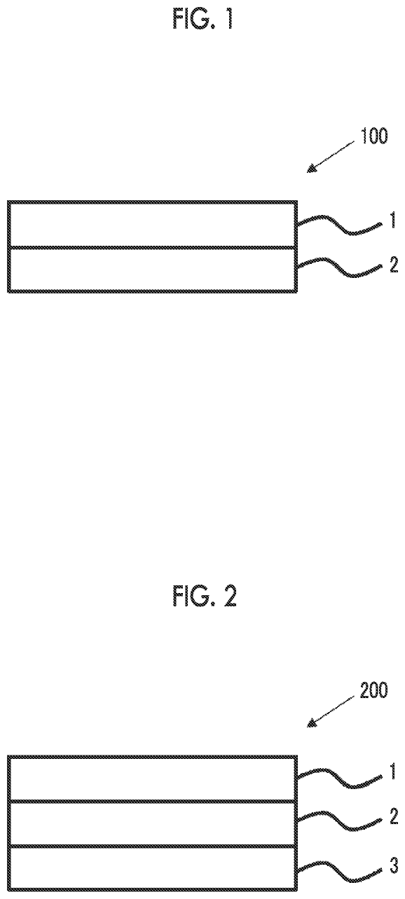

FIG. 1 is a schematic cross-sectional view showing an example of the laminate of the embodiment of the present invention. In FIG. 1, in a laminate 100, a photoalignment layer 2 and a liquid crystal layer 1 are laminated in this order.

FIG. 2 is a schematic cross-sectional view showing an example of the laminate of the embodiment of the present invention. In FIG. 2, in a laminate 200, a retardation layer 3, a photoalignment layer 2, and a liquid crystal layer 1 are laminated in this older.

Details of each layer in FIGS. 1 and 2 are as described above, and thus the description thereof will be omitted.

[Image Display Device]

The image display device of an embodiment of the present invention has the above-mentioned laminate of the embodiment of the present invention.

A display element used in the image display device of the embodiment of the present invention is not particularly limited, and examples thereof include a liquid crystal cell, an organic electroluminescence (hereinafter simply referred to as “EL”) display panel, and a plasma display panel.

Among those, a liquid crystal cell or an organic EL display panel is preferable and a liquid crystal cell is more preferable. That is, as the image display device of the embodiment of the present invention, a liquid crystal display device using a liquid crystal cell as a display element or an organic EL display device using an organic EL display panel (organic EL display element) as an image display element is preferable, and the liquid crystal display device is more preferable.

<Liquid Crystal Display Device>

The liquid crystal display device which is an example of the image display device of the embodiment of the present invention is a liquid crystal display device having the above-mentioned laminate of the embodiment of the present invention (however, a λ/4 plate is not included) and a liquid crystal cell.

In addition, in the present invention, among the laminates provided on both sides of the liquid crystal cell, the laminate of the embodiment of the present invention is preferably used as the front-side polarizing element, and the laminate of the embodiment of the present invention is more preferably used as the front-side and rear-side polarizing elements.

Hereinafter, the liquid crystal cell constituting the liquid crystal display device will be described in detail.

(Liquid Crystal Cell)

The liquid crystal cell used for the liquid crystal display device is preferably in a vertical alignment (VA) mode, an optically compensated bend (OCB) mode, an in-plane-switching (IPS) mode, or a twisted nematic (TN) mode, but is not limited thereto.

In a liquid crystal cell in the TN mode, rod-like liquid crystalline molecules (rod-like liquid crystalline compounds) are substantially horizontally aligned with, no application of a voltage, and twist-aligned by 60° to 120°. A TN-mode liquid crystal cell is most often used in a color TFT liquid crystal display device and described in numerous documents.

In a VA-mode liquid crystal cell, rod-shaped liquid crystal molecules are substantially vertically aligned during no voltage application thereto. The liquid crystal cell in the VA mode includes (1) a narrowly-defined liquid crystal cell in the VA mode in which rod-like liquid crystalline molecules are substantially vertically aligned with no application of a voltage, and are substantially horizontally aligned with the application of a voltage (described in JP1990-176625A (JP-H02-176625A)), (2) a liquid crystal cell (in the multi-domain vertical alignment (MVA) mode) in which the VA mode is made into multi-domains in order to expand the viewing angle (described in SID97, Digest of tech. Papers (proceedings) 28 (1997) 845), (3) an liquid crystal cell in a mode (the n-axially symmetric aligned microcell (AbM) mode) in which rod-like liquid crystalline molecules are substantially vertically aligned with no application of a voltage, and are twistedly aligned in multi-domains with the application of a voltage (described in the proceedings 58 and 59 of Japanese Liquid Crystal Conference (1998)), and (4) a liquid crystal cell in the SURVIVAL mode (announced at liquid crystal display (LCD) International 98). In addition, the liquid crystal cell in the VA mode may be any one of a patterned vertical alignment (PVA) type, an optical alignment type, and a polymer-sustained alignment (PSA). With respect to the details of these modes, detailed descriptions can be found in JP2006-215326A and JP2008-538819A.

In an IPS-mode liquid crystal cell, rod-shaped liquid crystalline molecules are aligned substantially parallel with respect to a substrate, and application of an electric field parallel to the substrate surface causes the liquid crystal molecules to respond planarly. The IPS mode displays black in a case where no electric field is applied and a pair of upper and lower polarizing plates have absorption axes which are orthogonal to each other. A method for improving the viewing angle by reducing light leakage during black display in an oblique direction using an optical compensation sheet is disclosed in JP1998-54982A (JP-H10-54982A), JP1999-202323A (JP-H11-202323A), JP1997-292522A (JP-H09-292522A), JP1999-133408A (JP-H11-133408A), JP1999-305217A (JP-H11-305217A), JP1998-307291A (JP-H10-307291A), and the like.

<Organic EL Display Device>

As an organic EL display device which is an example of the image display device of the embodiment of the present invention, for example, an aspect in which the above-mentioned laminate of the embodiment of the present invention (provided that the laminate includes a pressure sensitive adhesive layer and a λ/4 plate) and an organic EL display panel are provided in this order from the visually recognized side is suitably mentioned. In this case, in the laminate, a barrier layer provided as necessary, a cured layer provided as necessary, a liquid crystal layer (light absorbing anisotropic layer), a pressure sensitive adhesive layer, and a λ/4 plate are arranged in this order from the visually recognized side.

In addition, the organic EL display panel is a display panel configured using an organic EL element in which an organic light emitting layer (organic electroluminescent layer) is sandwiched between electrodes (between a cathode and an anode). The configuration of the organic EL display panel is not particularly limited, and known configurations are employed.

### EXAMPLES

Hereinafter, the present invention will be described in more detail with reference to Examples. The materials, the amounts of materials used, the ratios, the treatment details, the treatment procedure, or the like shown in the following Examples can be appropriately modified without departing from the spirit of the present invention. Therefore, the scope of the present invention will not be restrictively interpreted by the following Examples.

### Production Example 1

<Production of Cellulose Acylate Film 1>

(Production of Core Layer Cellulose Acylate Dope)

The following composition was introduced into a mixing tank and stirred to dissolve the respective components, thereby preparing a cellulose acetate solution used as a core layer cellulose acylate dope.

Core layer cellulose acylate dope

| | |
|---|---|
| Cellulose acetate having acetyl substitution | 100 parts by mass |
| degree of 2.88 | |
| Polyester compound B described in Examples of | 12 parts by mass |
| JP2015-227955A | |
| The following compound F | 2 parts by mass |
| Methylene chloride (first solvent) | 430 parts by mass |
| Methanol (second solvent) | 64 parts by mass |

Compound F

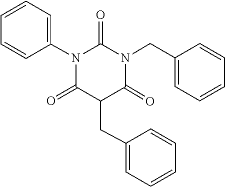

(Production of Outer Layer Cellulose Acylate Dope)

To 90 parts by mass of the core layer cellulose acylate dope was added 10 parts by mass of the following matting agent solution to prepare a cellulose acetate solution used as an outer layer cellulose acylate dope.

Matting agent solution

| | |
|---|---|
| Silica particles having average particle size of 20 nm | 2 parts by mass |
| (AEROSIL R972, manufactured by | |
| NIPPON AEROSIL CO., LTD.) | |
| Methylene chloride (first solvent) | 76 parts by mass |
| Methanol (second solvent) | 11 parts by mass |
| The core layer cellulose acylate dope | 1 part by mass |

(Production of Cellulose Acylate Film 1)

The core layer cellulose acylate dope and the outer layer cellulose acylate dope were filtered with filter paper having an average pore diameter of 34 μm and a sintered metal filter having an average pore diameter of 10 μm, and then three layers of the core layer cellulose acylate dope and the outer layer cellulose acylate dopes on both sides thereof were cast onto a dram at 20° C. from casting ports at the same time (band casting machine).

Subsequently, the film was peeled in the state where the solvent content reached approximately 20% by mass, the both ends of the film in the width direction were fixed with tenter clips, and the film was dried while being stretched at a stretching ratio of 1.1 times in the cross direction.

Thereafter, the film was transported between rolls in a heat treatment device and further dried to produce an optical film having a thickness of 40 μm, which was used as a cellulose acylate film 1. The in-plane retardation of the obtained cellulose acylate film 1 was 0 nm.

<Production of Transparent Support 1>

A coating liquid PA1 for forming a photoalignment layer, which will be described later, was continuously applied onto the cellulose acylate film 1 with a wire bar. The support on which the coating film was formed was dried with hot air at 140° C. for 120 seconds, and subsequently, the coating film was irradiated with polarized ultraviolet rays (10 mJ/cm², using an ultra-high-pressure mercury lamp) to form a photoalignment layer PA1, whereby a TAG film with a photoalignment layer was obtained. The film thickness thereof was 1.0 μm.

(Coating liquid PA1 for Forming Photoalignment Layer)

| | |
|---|---|
| The following polymer PA-1 | 100.00 parts by mass |
| The following acid generator PAG-1 | 5.00 parts by mass |
| The following acid generator CPI-110TF | 0.005 parts by mass |
| Xylene | 1,220.00 parts by mass |
| Methyl isobutyl ketone | 122.00 parts by mass |

Polymer PA-1 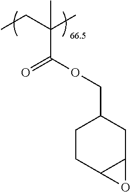 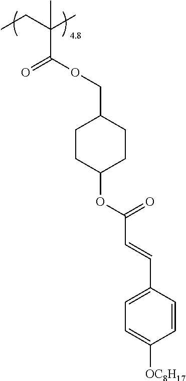 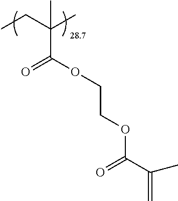
Acid generator PAG-1 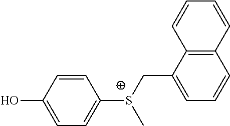 [SMILES: C[S+](Cc1cccc2ccccc12)c1ccc(O)cc1] 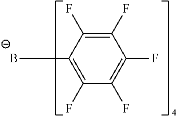
Acid generator CPI-110TF

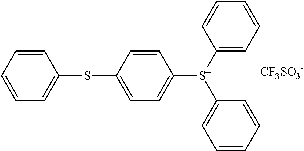

<Formation of Liquid Crystal Layer P1>

The following liquid crystal composition P1 was continuously applied onto the obtained alignment layer PA1 with a wire bar to form a coating film P1.

Next, the coating film P1 was heated at 140° C. for 30 seconds, and the coating film P1 was cooled to room temperature (23° C.).

Subsequently, the coating layer was heated at 9° C. for 60 seconds and cooled again to room temperature.

Thereafter, the coating layer was irradiated with light for 2 seconds under an irradiation condition of an illuminance of 200 mW/cm², using a LED lamp (center wavelength of 365 nm), to produce a liquid crystal layer P1 on the alignment layer PA1. The film thickness thereof was 0.4 μm.

In this way, a laminate of Production Example 1 was obtained.

Composition of liquid crystal composition P1

| | |
|---|---|
| The following dichroic substance D-1 | 0.36 parts by mass |
| The following dichroic substance D-2 | 0.53 parts by mass |
| The following dichroic substance D-3 | 0.31 parts by mass |
| The following high-molecular-weight liquid crystalline compound P-1 | 3.58 parts by mass |
| Polymerization initiator | 0.050 parts by mass |
| IRGACURE OXE-02 (manufactured by BASF SE) | |
| The following surfactant F-1 | 0.026 parts by mass |
| Cyclopentanone | 45.00 parts by mass |
| Tetrahydrofuran | 45.00 parts by mass |
| Benzyl alcohol | 5.00 parts by mass |

D-1 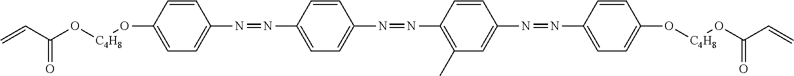
D-2 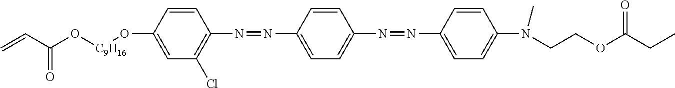
D-3 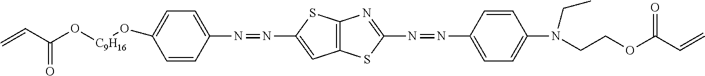
High-molecular-weight liquid crystalline compound P-1 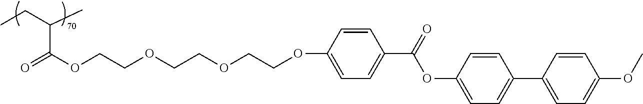 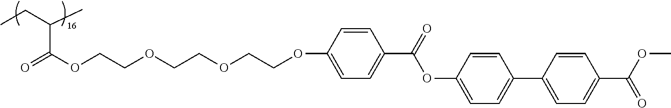 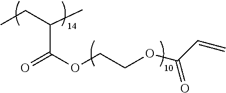
Surfactant F-1

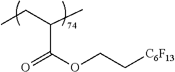

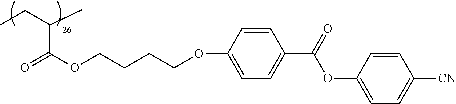

### Production Examples 2 to 6

Laminates of Production Examples 2 to 6 were produced in the same manner as in Production Example 1, except that the liquid crystal compositions P2 to P6 in which the surfactant F-1 of the liquid crystal composition P1 was replaced by F-2 to F-6 shown below were used.

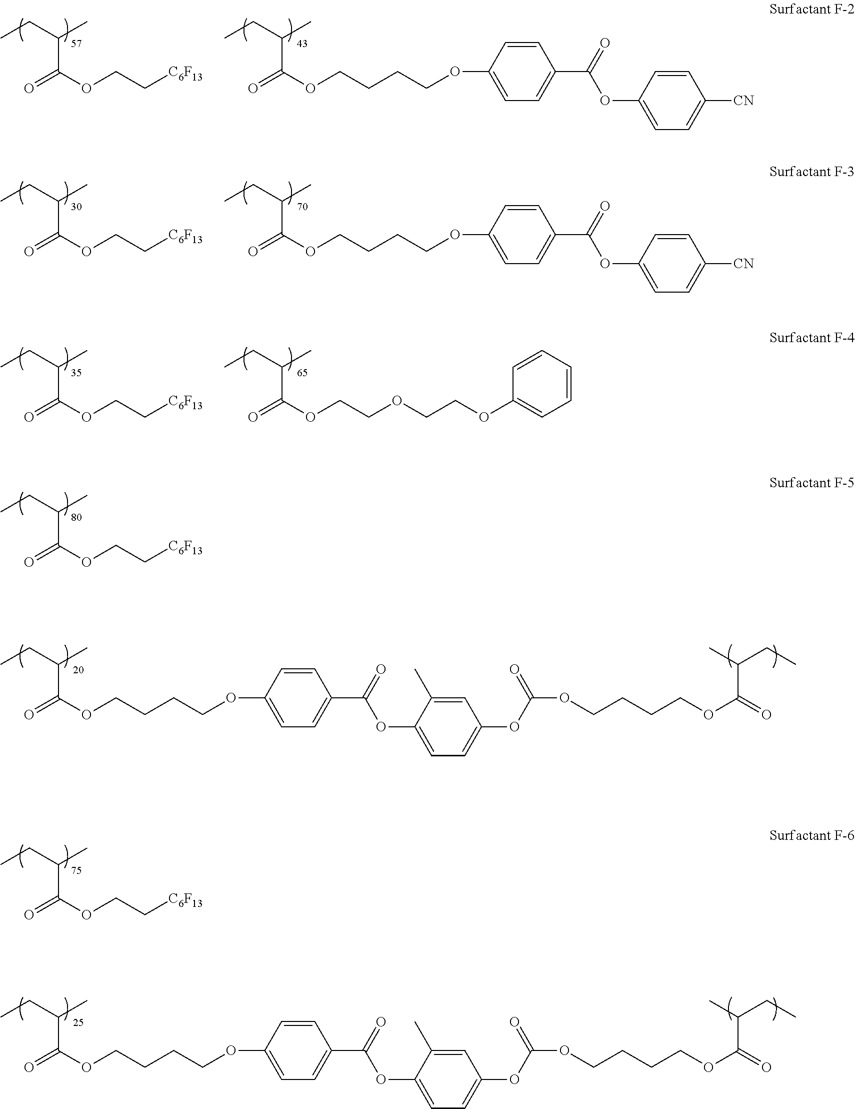

### Production Example 7

A laminate of Production Example/was produced in the same manner as in Production Example 1, except that the liquid crystal composition P1 was replaced by P7 shown below.

Composition of liquid crystal composition P7

| | |
|---|---|
| The dichroic substance D-1 | 0.21 parts by mass |
| The dichroic substance D-2 | 0.31 parts by mass |
| The dichroic substance D-3 | 0.18 parts by mass |
| The high-molecular-weight liquid | 4.08 parts by mass |
| crystalline compound P-1 | |
| Polymerization initiator | 0.050 parts by mass |
| IRGACURE OXE-02 (manufactured by BASF SE) | |
| The surfactant F-2 | 0.026 parts by mass |
| Cyclopentanone | 45.00 parts by mass |
| Tetrahydrofuran | 45.00 parts by mass |
| Benzyl alcohol | 5.00 parts by mass |

### Production Example 8

A laminate of Production Example 8 was produced in the same manner as in Production Example 1, except that the liquid crystal composition P1 was replaced by P8 shown below.

Composition of liquid crystal composition P8

| | |
|---|---|
| The following dichroic substance D-4 | 0.36 parts by mass |
| The following dichroic substance D-5 | 0.53 parts by mass |
| The following dichroic substance D-6 | 0.31 parts by mass |
| The following high-molecular-weight liquid crystalline compound P-2 | 3.42 parts by mass |
| The following low-molecular-weight liquid crystalline compound M-1 | 0.36 parts by mass |
| Polymerization initiator | 0.050 parts by mass |
| IRGACURE OXE-02 (manufactured by BASF SE) | |
| The surfactant F-2 | 0.026 parts by mass |
| Cyclopentanone | 45.00 parts by mass |
| Tetrahydrofuran | 45.00 parts by mass |
| Benzyl alcohol | 5.00 parts by mass |

D-4 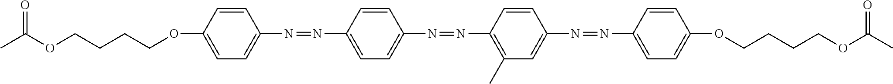 [SMILES: CC(=O)OCCCCOc1ccc(N=Nc2ccc(N=Nc3ccc(N=Nc4ccc(OCCCCOC(C)=O)cc4)cc3C)cc2)cc1]
D-5 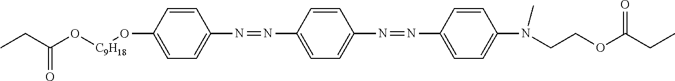
D-6 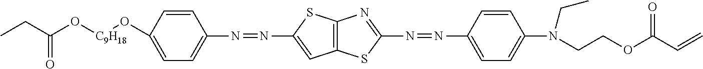
High-molecular-weight liquid crystalline compound P-2 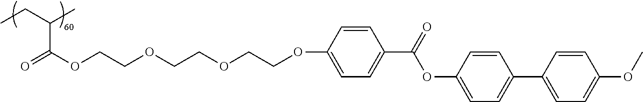 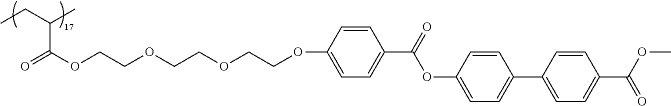 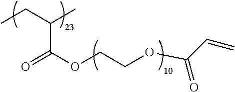
Low-molecular-weight liquid crystalline compound M-1

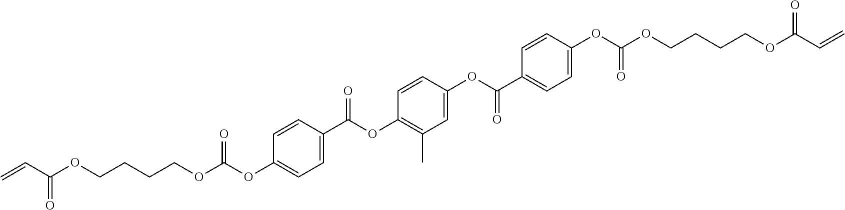 [SMILES: C=CC(=O)OCCCCOC(=O)Oc1ccc(C(=O)Oc2ccc(OC(=O)c3ccc(OC(=O)OCCCCOC(=O)C=C)cc3)c(C)c2)cc1]

### Production Example 9

A laminate of Production Example 9 was produced in the same manner as in Production Example 2, except that the coating liquid PA1 for forming a photoalignment layer was replaced by PA2 shown below.

(Coating liquid PA2 for forming photoalignment layer)

| | |
|---|---|
| The following polymer PA-2 | 100.00 parts by mass |
| The acid generator PAG-1 | 5.00 parts by mass |
| The acid generator CPI-110TF | 0.005 parts by mass |
| Isopropyl alcohol | 16.50 parts by mass |
| Butyl acetate | 1,072.00 parts by mass |
| Methyl ethyl ketone | 268.00 parts by mass |

Polymer PA-2

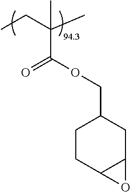

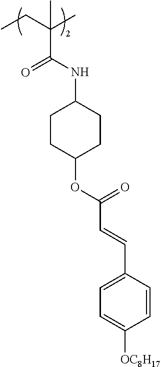

### Production Example 10

A laminate of Production Example 10 was produced in the same manner as in Production Example 3, except that the coating liquid PA1 for forming a photoalignment layer was replaced by PA2 shown above.

### Production Example 11

A laminate of Production Example 11 was produced in the same manner as in Production Example 2, except that the coating liquid PA1 for forming a photoalignment layer was replaced by PA3 shown below.

(Coating liquid PA3 for forming photoalignment layer)

| | |
|---|---|
| The following polymer PA-3 | 100.00 parts by mass |
| The acid generator PAG4 | 5.00 parts by mass |
| The acid generator CPI-110TF | 0.005 parts by mass |
| Xylene | 1,220.00 parts by mass |
| Methyl isobutyl ketone | 122.00 parts by mass |

Polymer PA-3

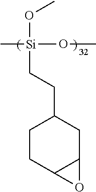

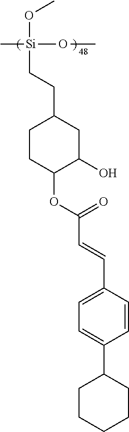

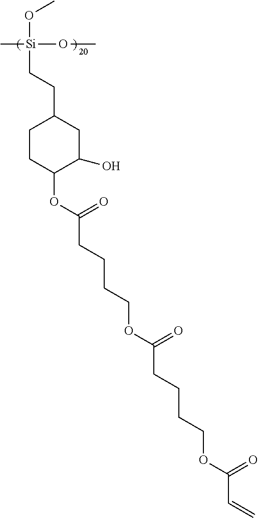

### Production Example 12

A laminate of Production Example 12 was produced in the same manner as in Production Example 3, except that the coating liquid PA1 for forming a photoalignment layer was replaced by PAS shown above.

### Production Examples 13 and 14

Laminates of Production Examples 13 and 14 were manufactured in the same as in Production Example 1, except that the liquid crystal compositions P9 and P10 in which the surfactant F-1 of the liquid crystal composition P1 was replaced by the additives H-1 and H-3 described in JP2006-16599A were used.

### Production Examples 15 to 17

Laminates of Production Examples 15 to 17 were produced in the same manner as in Production Example 1, except that, the liquid crystal compositions P11 to P13 in which the surfactant F-1 of the liquid crystal composition P1 was replaced by F-7 to F-9 shown below were used.

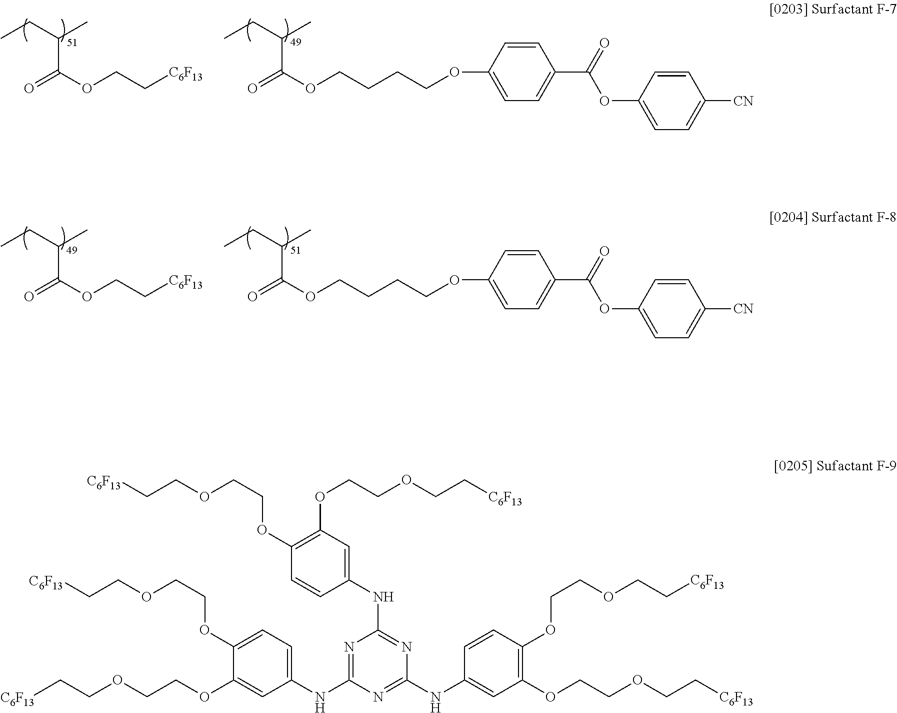

<Evaluation of Alignment Degree>

Each of the laminates of Production Examples was set on a sample table in a state where a linear polarizer was inserted into the side of a light source of an optical microscope (manufactured by Nikon Corporation, trade name “ECLIPSE E600 POL”), and a light absorbance of the liquid crystal layer in a wavelength range of 400 to 700 nm was measured using a multi-channel spectrometer (manufactured by Ocean Optics Inc., trade name “QE65000”), and an alignment degree was calculated by the following expression and evaluated according to the following standard. The results are shown in Table 1 below.

Alignment degree; S=[(Az0/Ay0)−1]/[(Az0/Ay0)+2]

Az0: Absorbance of the liquid crystal layer with respect to polarized light in the absorption axis direction

Ay0: Absorbance of the liquid crystal layer with respect to polarized light in the polarization axis direction

(Standard for Evaluation of Alignment Degree)

A: 0.96 or more

B: 0.90 or more and less than 0.96

C: Less than 0.90

TABLE 1

| | Photoalignment | Liquid crystal layer | | | Evaluation | |
|---|---|---|---|---|---|---|
| | layer | Type of | Surfactant | | results | |
| | Type of coating | liquid crystal | | Content of | Alignment | |
| | liquid | composition | Type | fluorine | degree | |
| Production | PA1 | P1 | F-1 | 45.6% | A | Example |
| Example 1 | | | | | | |
| Production | PA1 | P2 | F-2 | 36.1% | A | Example |
| Example 2 | | | | | | |
| Production | PA1 | P3 | F-3 | 19.9% | C | Comparative |
| Example 3 | | | | | | Example |
| Production | PA1 | P4 | F-4 | 28.8% | C | Comparative |
| Example 4 | | | | | | Example |
| Production | PA1 | P5 | F-5 | 43.2% | B | Example |
| Example 5 | | | | | | |
| Production | PA1 | P6 | F-6 | 40.3% | B | Example |
| Example 6 | | | | | | |
| Production | PA1 | P7 | F-2 | 36.1% | B | Example |
| Example 7 | | | | | | |
| Production | PA1 | P8 | F-2 | 36.1% | A | Example |
| Example 8 | | | | | | |
| Production | PA2 | P2 | F-2 | 36.1% | A | Example |
| Example 9 | | | | | | |
| Production | PA2 | P3 | F-3 | 19.9% | C | Comparative |
| Example 10 | | | | | | Example |
| Production | PA3 | P2 | F-2 | 36.1% | A | Example |
| Example 11 | | | | | | |
| Production | PA3 | P3 | F-3 | 19.9% | C | Comparative |
| Example 12 | | | | | | Example |
| Production | PA1 | P9 | H-1 | 20.0% | C | Comparative |
| Example 13 | | | | | | Example |
| Production | PA1 | P10 | H-3 | 29.0% | C | Comparative |
| Example 14 | | | | | | Example |
| Production | PA1 | P11 | F-7 | 32.6% | B | Example |
| Example 15 | | | | | | |
| Production | PA1 | P12 | F-8 | 31.4% | C | Comparative |
| Example 16 | | | | | | Example |
| Production | PA1 | P13 | F-9 | 53.1% | C | Comparative |
| Example 17 | | | | | | Example |

As shown in Table 1, the laminate of the embodiment of the present invention, obtained by using the surfactant having a content, of fluorine of 32% by mass or more, had a highly excellent alignment degree.

<Evaluation of Cissing>

A surface of the liquid crystal layer of the laminate obtained above was visually observed, and the cissing was evaluated according to the following standard. The results are shown in Table 2 below.

Standard for Evaluation of Cissing

A: Less than one cissing/m² are present

B: One cissing/m² or more and two cissings/m² or less are present

C: Two cissings/m² or more are present

TABLE 2

| | Photoalignment layer | Liquid crystal layer | | | Evaluation | |
|---|---|---|---|---|---|---|
| | Type of | Type of liquid | Surfactant | | results | |
| | coating liquid | crystal composition | Type | δd | Cissing | |
| Production | PA1 | P1 | F-1 | 15 | C | Example |
| Example 1 | | | | | | |
| Production | PA1 | P2 | F-2 | 15.9 | A | Example |
| Example 2 | | | | | | |
| Production | PA1 | P3 | F-3 | 17.3 | A | Comparative |
| Example 3 | | | | | | Example |
| Production | PA1 | P4 | F-4 | 15.8 | A | Comparative |
| Example 4 | | | | | | Example |
| Production | PA1 | P5 | F-5 | 15.2 | C | Example |
| Example 5 | | | | | | |
| Production | PA1 | P6 | F-6 | 15.5 | B | Example |
| Example 6 | | | | | | |
| Production | PA1 | P7 | F-2 | 15.9 | A | Example |
| Example 7 | | | | | | |
| Production | PA1 | P8 | F-2 | 15.9 | A | Example |
| Example 8 | | | | | | |
| Production | PA2 | P2 | F-2 | 15.9 | A | Example |
| Example 9 | | | | | | |
| Production | PA2 | P3 | F-3 | 17.3 | A | Comparative |
| Example 10 | | | | | | Example |
| Production | PA3 | P2 | F-2 | 15.9 | A | Example |
| Example 11 | | | | | | |
| Production | PA3 | P3 | F-3 | 17.3 | A | Comparative |
| Example 12 | | | | | | Example |
| Production | PA1 | P11 | F-7 | 16.2 | A | Example |
| Example 15 | | | | | | |
| Production | PA1 | P12 | F-8 | 16.3 | A | Comparative |
| Example 16 | | | | | | Example |

As shown in Table 2, it was found that in a case where the δd of the surfactant was in the range of 15.5 to 17.5, the cissing was suppressed. In addition, it was also found that the cissing was further improved in a case where the δd was 15.8 or more.

### Production of Production Example 18

<Formation of Cured Layer N1>

The following composition N1 for forming a cured layer (simply referred to as “Composition A” in Table 1 below) was continuously applied onto the liquid crystal layer P1 of the laminate 1 of Production Example 1 with a wire bar to form a cured layer N1.

Subsequently, the cured layer N1 was dried at room temperature and then irradiated with light for 15 seconds under an irradiation condition of an illuminance of 28 mW/cm², using a high-pressure mercury lamp, to produce the cured layer N1 on the liquid crystal layer P1.

A film thickness of the cured layer N1 was 0.05 μm (50 nm).

Composition of composition N1 for forming cured layer

| | |
|---|---|
| The following mixture L1 of rod-like liquid | 2.61 parts by mass |
| crystalline compounds | |
| The following modified trimethylol propane | 0.11 parts by mass |
| triacrylate | |
| The following photopolymerization initiator I-1 | 0.05 parts by mass |
| The following interface modifier FB-3 | 0.21 parts by mass |
| Methyl isobutyl ketone | 297 parts by mass |

Mixture L1 of rod-like liquid crystalline compounds (the numerical values in the
following formulae represent % by mass, and R represents a group bonded to an oxygen
atom.) 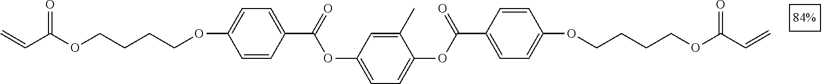 [SMILES: C=CC(=O)OCCCCOc1ccc(C(=O)Oc2ccc(OC(=O)c3ccc(OCCCCOC(=O)C=C)cc3)c(C)c2)cc1] 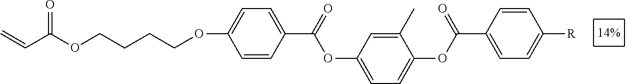 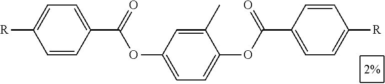 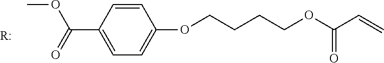
Modified trimethylol propane triacrylate 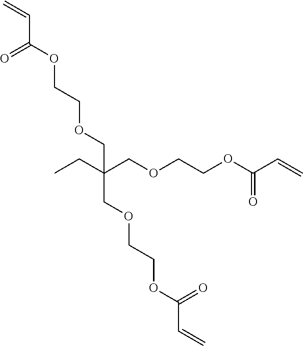 [SMILES: C=CC(=O)OCCOCC(CC)(COCCOC(=O)C=C)COCCOC(=O)C=C]
The following photopolymerization initiator I-1 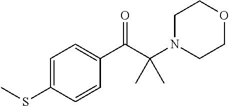 [SMILES: CSc1ccc(C(=O)C(C)(C)N2CCOCC2)cc1]
Interface modifier FB-3

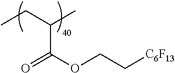

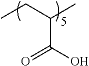

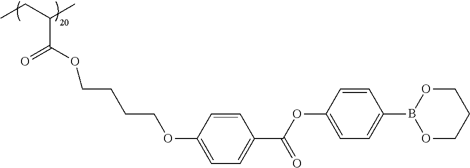

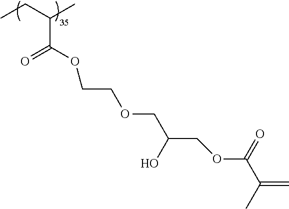

<Formation of Oxygen Shielding Layer B1>

A coating liquid having the following composition was continuously applied onto the cured layer N1 with a wire bar. Thereafter, the composition liquid was dried with hot air at 100° C. for 2 minutes to produce a laminate 18B in which an oxygen shielding layer B1 having a thickness of 1.0 μm was formed on the cured layer N1.

Composition of composition B1 for forming oxygen shielding layer

| | |
|---|---|
| The following modified polyvinyl alcohol | 3.80 parts by mass |
| Initiator Irg2959 | 0.20 parts by mass |
| Water | 70 parts by mass |
| Methanol | 30 parts by mass |

Modified polyvinyl alcohol

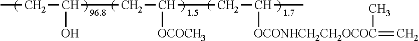

<Production of Optically Anisotropic Layer>

(Production of Positive A-Plate A1)

The coating liquid PA2 for forming a photoalignment layer was continuously applied onto the cellulose acylate film 1 with a wore bar. The support on which the coating film was formed was dried with hot air at 140° C. tor 120 seconds, and subsequently, the coating film was irradiated with polarized ultraviolet rays (10 mJ/cm², using an ultra-high-pressure mercury lamp) to form an alignment layer PA2 having a thickness of 0.2 μm, thereby obtaining a TAG film with a photoalignment layer.

A composition A1 having the following composition was applied onto the alignment layer PA2 using a bar coater. A coating film formed on the alignment layer PA2 was heated to 120° C. with hot air and then cooled to 60° C., and the alignment of the liquid crystalline compound was immobilized by irradiating the coating film with ultraviolet rays at 100 ml/cm at a wavelength of 365 nm using a high-pressure mercury lamp in a nitrogen atmosphere, and subsequently irradiating the coating film with ultraviolet rays at 500 mJ/cm² while heating to 120° C., thereby producing a TAG film A1 having a positive A-plate A1.

The thickness and Re(550) of the positive A-plate A1 were 2.5 μm an 144 nm, respectively. Moreover, the positive A-plate A1 satisfied a relationship of Re(450)≤Re(550)≤Re(650). Re(450)/Re(550) was 0.82.

Composition A1

| | |
|---|---|
| The following polymerizable liquid crystalline | 43.50 parts by mass |
| compound L-1 | |
| The following polymerizable liquid crystalline | 43.50 parts by mass |
| compound L-2 | |
| The following polymerizable liquid crystalline | 8.00 parts by mass |
| compound L-3 | |
| The following polymerizahle liquid crystalline | 5.00 parts by mass |
| compound L-4 | |
| The following polymerization initiator PI-1 | 0.55 parts by mass |
| The following leveling agent T-1 | 0.20 parts by mass |
| Cyclopentanone | 235.00 parts by mass |

Polymerizable liquid crystalline compound L-1 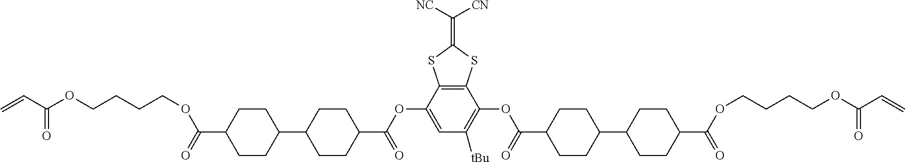 [SMILES: C=CC(=O)OCCCCOC(=O)C1CCC(C2CCC(C(=O)Oc3cc(C(C)(C)C)c(OC(=O)C4CCC(C5CCC(C(=O)OCCCCOC(=O)C=C)CC5)CC4)c4c3SC(=C(C#N)C#N)S4)CC2)CC1]
Polymerizable liquid crystalline compound L-2 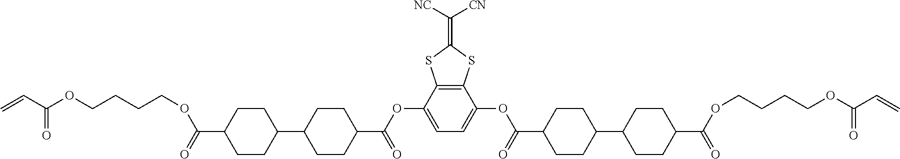 [SMILES: C=CC(=O)OCCCCOC(=O)C1CCC(C2CCC(C(=O)Oc3ccc(OC(=O)C4CCC(C5CCC(C(=O)OCCCCOC(=O)C=C)CC5)CC4)c4c3SC(=C(C#N)C#N)S4)CC2)CC1]
Polymerizable liquid crystalline compound L-3 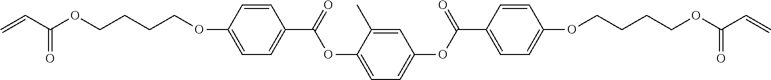 [SMILES: C=CC(=O)OCCCCOc1ccc(C(=O)Oc2ccc(OC(=O)c3ccc(OCCCCOC(=O)C=C)cc3)c(C)c2)cc1]
Polymerizable liquid crystalline compound L-4 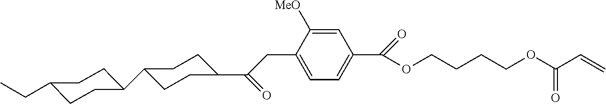 [SMILES: C=CC(=O)OCCCCOC(=O)c1ccc(CC(=O)C2CCC(C3CCC(CC)CC3)CC2)c(OC)c1]
Polymerization initiator PI-1 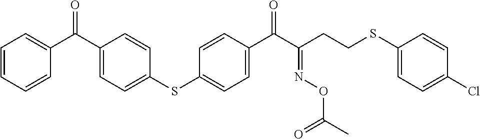 [SMILES: CC(=O)O/N=C(\CCSc1ccc(Cl)cc1)C(=O)c1ccc(Sc2ccc(C(=O)c3ccccc3)cc2)cc1]
Leveling agent T-1

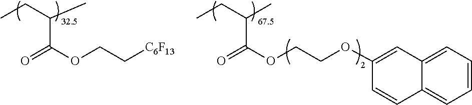

(Production of Positive C-Plate C1)

The cellulose acylate film 1 was used as a temporary support.

The cellulose acylate film 1 was allowed to pass through a dielectric heating roll at a temperature of 60° C., the film surface temperature was raised to 40° C., then an alkali solution having the following composition was applied onto one surface of the film at an application amount of 14 ml/m² using a bar coater, and the film was heated to 110° C. and transported for 10 seconds under a steam-type far infrared heater manufactured by NORITAKE CO., LIMITED.

Next, pure water was applied onto the film at 3 ml/m² with the same bar coater.

Subsequently, water-washing using a fountain coater and drainage using an air knife were repeated three times, and then the film was transported to a drying zone at 70° C. for 10 seconds for drying to produce a cellulose acylate film 1 which had been subjected to an alkali saponification treatment.

Alkali solution

| | |
|---|---|
| Potassium hydroxide | 4.7 parts by mass |
| Water | 15.8 parts by mass |
| Isopropanol | 63.7 parts by mass |
| Fluorine-containing surfactant SF-1 | 1.0 part by mass |
| (C₁₄H₂₉O(CH₂CH₂O)₂₀H) | |
| Propylene glycol | 14.8 parts by mass |

A coating liquid 3 for forming an alignment layer having the following composition was continuously applied onto the cellulose acylate film 1, which had been subjected to an alkali saponification treatment, with a wire bar of #8. The obtained film was dried with hot air at 60° C. for 60 seconds, and further dried with hot air at 100° C. for 120 seconds to form an alignment layer.

(Coating liquid 3 for forming alignment layer)

| | |
|---|---|
| Polyvinyl alcohol (PVA 103, manufactured | 2.4 parts by mass |
| by KURARAY CO., LTD.) | |
| Isopropyl alcohol | 1.6 parts by mass |
| Methanol | 36 parts by mass |
| Water | 60 parts by mass |

A coating liquid C1 for forming a positive C-plate, which will be described later, was applied onto the alignment layer, the obtained coating film was aged at 60° C. for 60 seconds, and then irradiated with ultraviolet rays at 1,000 mJ/cm² in air using an air-cooled metal halide lamp (manufactured by EYE GRAPHICS Co., Ltd.) at 70 mW/cm², and the alignment state was immobilized to vertically align a liquid crystalline compound, thereby producing a positive C-plate 1 having a thickness of 0.5 μm.

The Rth (550) of the obtained positive C-plate was −60 nm.

(Coating liquid C1 for forming positive C-plate)

| | |
|---|---|
| The following liquid crystalline compound L-11 | 80 parts by mass |
| The following liquid crystalline compound L-12 | 20 parts by mass |
| The following vertical alignment agent (S01) for liquid crystalline compound | 1 part by mass |
| Ethylene oxide-modified trimethylol propane triacrylate | 8 parts by mass |
| (V#360, manufactured by Osaka Organic Chemical Industry, Ltd.) | |
| IRGACURE 907 (manufactured by BASF SF) | 3 parts by mass |
| KAYACURE DETX (manufactured by Nippon Kayaku Co., Ltd.) | 1 part by mass |
| The following compound B03 | 0.4 parts by mass |
| Methyl ethyl ketone | 1.70 parts by mass |
| Cyclohexanone | 30 parts by mass |

L-11 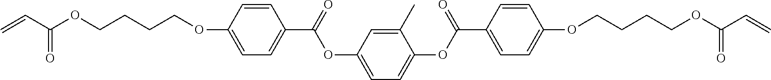 [SMILES: C=CC(=O)OCCCCOc1ccc(C(=O)Oc2ccc(OC(=O)c3ccc(OCCCCOC(=O)C=C)cc3)c(C)c2)cc1]
L-12 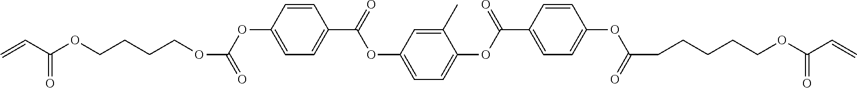 [SMILES: C=CC(=O)OCCCCCC(=O)Oc1ccc(C(=O)Oc2ccc(OC(=O)c3ccc(OC(=O)OCCCCOC(=O)C=C)cc3)cc2C)cc1]
S01 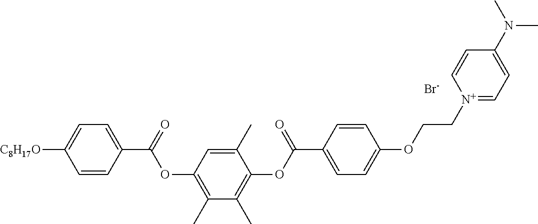
B03

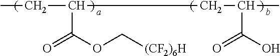

<Production of Pressure-Sensitive Adhesives N1 and N2>

Next, an acrylate-based polymer was prepared according to the following procedure.

In a reaction vessel comprising a cooling pipe, a nitrogen introduction pipe, a thermometer, and a stirrer, 95 parts by weight of butyl acrylate and 5 parts by weight of acrylic acid were polymerized by a solution polymerization method to obtain an acrylate-based polymer A1 having an average molecular weight of 2,000,000 and a molecular weight distribution (Mw/Mn) of 3.0.

Next, an acrylate-based pressure sensitive adhesive was produced with the composition shown in Table 1 below, using the obtained acrylate-based polymer A1. The composition was applied onto a separate film which had been surface-treated with a silicone-based release agent, using a die coater, dried in an environment of 90° C. for 1 minute, and irradiated with ultraviolet rays (UV) under the following conditions to obtain pressure sensitive adhesives N1 and N2. The composition, the film thickness, and the storage elastic modulus of the pressure sensitive adhesive are shown in Table 3 below.

<Conditions for UV Irradiation>
Electrodeless lamp H BULB, Fusion Corporation
Illuminance of 600 mW/cm² and light quantity of 150 mJ/cm²
The illuminance and the light quantity of UV were measured using “UVPF-36” manufactured by EYE GRAPHICS Co., Ltd.

TABLE 3

| | Composition of pressure sensitive adhesive | | | | | |
|---|---|---|---|---|---|---|
| | | (A) | | (C) | (D) | |
| | | Polyfunctional | (B) | Isocyanate-based | Silane | Film |
| | Acryl-based | acrylate-based | Photopolymerization | crosslinking | coupling | thickness |
| | polymer A1 | monomer | initiator | agent | agent | (μm) |
| Pressure sensitive | 100 | 11.1 | 1.1 | 1 | 0.2 | 5 |
| adhesive N1 | | | | | | |
| Pressure sensitive | 100 | — | — | 1 | 0.2 | 25 |
| adhesive N2 | | | | | | |

(A) Polyfunctional acrylate-based monomer: Tris(acryloyloxyethyl) isocyanurate, molecular weight = 423, and trifunctional type (manufactured by Toagosei Co., Ltd., trade name “ARONIX M-315”)
(B) Photopolymerization initiator: Mixture of benzophenone and 1-hydroxycyclohexyl phenyl ketone at a mass ratio of 1:1, and “IRGACURE 500” manufactured by Ciba Specialty Chemicals Inc.
(C) Isocyanate-based crosslinking agent: Trimethylol propane-modified tolylene diisocyanate (“CORONATE L” manufactured by Nippon Polyurethane Industry Co., Ltd.)
(D) Silane coupling agent: 3-Glycidoxypropyl trimethoxysilane (“KBM-403” manufactured by Shin-Etsu Chemical Co., Ltd.)

<Production of UV Adhesive>

The following UV adhesive composition was prepared.

UV adhesive composition

| | |
|---|---|
| CEL2021P (manufactured by Daicel Corporation) | 70 parts by mass |
| 1,4-Butanediol diglycidyl ether | 20 parts by mass |
| 2-Ethylhexyl glycidyl ether | 10 parts by mass |
| CPI-100P | 2.25 parts by mass |

CPI-100P

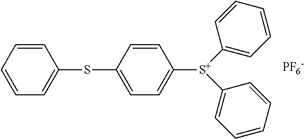

<Production of Laminate of Production Example 18>

The phase difference side of the positive A-plate A1 was bonded to the phase difference side of the positive C-plate C1 by UV irradiation at 600 mJ/cm² using a UV adhesive. The thickness of the UV adhesive layer was 3 μm. Moreover, the surfaces to be bonded with the UV adhesive were each subjected to a corona treatment. Next, the alignment layer on the positive A-Plate A1 side and the cellulose acylate film 1 were removed to obtain a phase difference plate 1.

The oxygen shielding layer side of the laminate 18B was bonded to the support side of a low-reflection surface film CV-LC5 (manufactured by FUJIFILM Corporation), using the pressure sensitive adhesive N1. Next, only the cellulose acylate film 1 was removed, and the surface obtained by the removal was bonded to the phase difference side of the positive A-plate A1 of the phase difference plate 1, using the pressure sensitive adhesive N1, to produce a laminate 18 of Production Example 18. At this time, the bonding was performed so that the angle formed by the absorption axis of the obtained liquid absorbing anisotropic layer and the slow axis of the positive A-plate A1 was 45°.

[Production of Laminates of Production Examples 19 to 26]

In the same manner as the laminate 18 of Production Example 18, laminates 19 to 26 were produced, using the laminates of Production Example 2, 5 to 9, 11, and 15 instead of the laminate of Production Example 1.

<Production of Organic EL Display Device>

GALAXY S4 manufactured by SAMSUNG, having an organic EL panel (organic EL display element) installed therein, was disassembled, the touch panel with a circularly polarizing plate was peeled from the organic EL display device, the circularly polarizing plate was further peeled from the touch panel, and the organic EL display element, the touch panel, and the circularly polarizing plate were each isolated. Subsequently, the isolated touch panel was adhered again to the organic EL display element, and each of the laminates of Production Examples 18 to 26 was bonded to the touch panel, using a pressure sensitive adhesive N2, to produce an organic EL display device, and it was confirmed that an antireflection effect was exhibited.

### EXPLANATION OF REFERENCES

100, 200: laminate
1: liquid crystal layer
2: alignment layer
3: retardation layer

What is claimed is:

1. A liquid crystal composition comprising at least:
a liquid crystalline compound;
a surfactant; and
a dichroic substance,
wherein the surfactant is a copolymer having a repeating unit including an alkyl fluoride group and a repeating unit including a ring structure, and a content of fluorine of the surfactant is 32% by mass or more.

2. The liquid crystal composition according to claim 1,
wherein a content of the dichroic substance is 2 to 200 parts by mass with respect to 100 parts by mass of the liquid crystalline compound.

3. The liquid crystal composition according to claim 1,
wherein the repeating unit including a ring structure is a repeating unit including two or more ring structures.

4. The liquid crystal, composition according to claim 1,
wherein the repeating unit including a ring structure includes a group represented by Formula (ca), 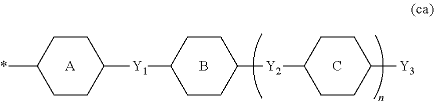
in Formula (ca), A, B, and C which are each a 6-membered ring each independently represent any of Formulae (ca1) to (ca10), Y₁ and Y₂ each independently represent a single bond, —CH₂CH₂—CH₂O—, —OCH₂—, —COO—, —OCO—, —OC—, —CH═CH—, —CF═CF—, —(CH₂)₄—, —CH₂CH₂CH₂O—, —OCH₂CH₂CH₂—, —CH₂═CHCH₂CH₂—, or —CH₂CH₂CH═CH—, Y₃ represents a hydrogen atom, a halogen atom, a cyano group, an alkyl group having 1 to 20 carbon atoms, an alkoxy group, an alkenyl group, or an alkenyloxy group, n represents an integer of 0 or 1, and * represents a bonding position to another group, 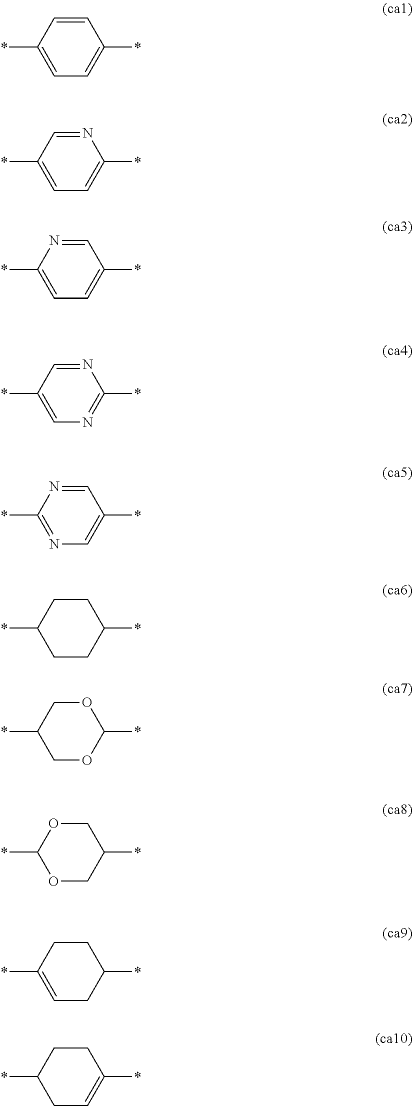
in Formulae (ca1) to (ca10), * represents a bonding position to another group, a left-side bonding site corresponds to a left-side bonding site in A, B, and C of Formula (ca), a right-side bonding site corresponds to a right-side bonding site in A, B, and C of Formula (ca), and a hydrogen atom bonded to a carbon atom that forms a ring in Formulae (ca1) to (ca10) may be substituted with a fluorine atom or a methyl group.

5. The liquid crystal composition according to claim 1,
wherein a dispersion terra δd of a Hansen solubility parameter of the surfactant is in a range of 15.5 to 17.5.

6. The liquid crystal composition according to claim 1,
wherein the liquid crystalline compound is a high-molecular-weight liquid crystalline compound.

7. A liquid crystal layer formed of the liquid crystal composition according to claim 1.

8. A laminate comprising at least:
a photoalignment layer; and
the liquid crystal layer according to claim 7 provided on the photoalignment layer,
wherein the liquid crystalline compound included in the liquid crystal layer is immobilized in a horizontally aligned state.

9. The laminate according to claim 8,
wherein a content of the dichroic substance included in the liquid crystal layer is 3% to 35% by mass with respect to a total solid content of the liquid crystal layer.

10. The laminate according to claim 8,
wherein the photoalignment layer contains a compound having a photoaligned group, and
the photoaligned group is a group having a cinnamoyl structure.

11. The laminate according to claim 8, further comprising a λ/4 plate provided on the liquid crystal layer.

12. An image display device comprising:
the laminate according to claim 8; and
an image display element.

13. The image display device according to claim 12,
wherein the image display element is an organic EL display element.

14. The liquid crystal composition according to claim 2,
wherein the repeating unit including a ring structure is a repeating unit including two or more ring structures.

15. The liquid crystal composition according to claim 2,
wherein the repeating unit including a ring structure includes a group represented by Formula (ca), 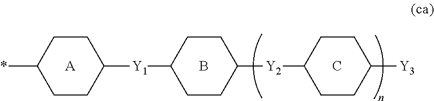
in Formula (ca), A, B, and C which are each a 6-membered ring each independently represent any of Formulae (ca1) to (ca10), Y₁ and Y₂ each independently represent a single bond, —CH₂CH₂—CH₂O—, —OCH₂—, —COO—, —OCO—, —C≡C—, —CH═CH—, —CF═CF—, —(CH₂)₄—, —CH₂CH₂CH₂O—, —OCH₂CH₂CH₂—, —CH₂═CHCH₂CH₂—, or —CH₂CH₂CH═CH—, Y₃ represents a hydrogen atom, a halogen atom, a cyano group, an alkyl group having 1 to 20 carbon atoms, an alkoxy group, an alkenyl group, or an alkenyloxy group, n represents an integer of 0 or 1, and * represents a bonding position to another group, 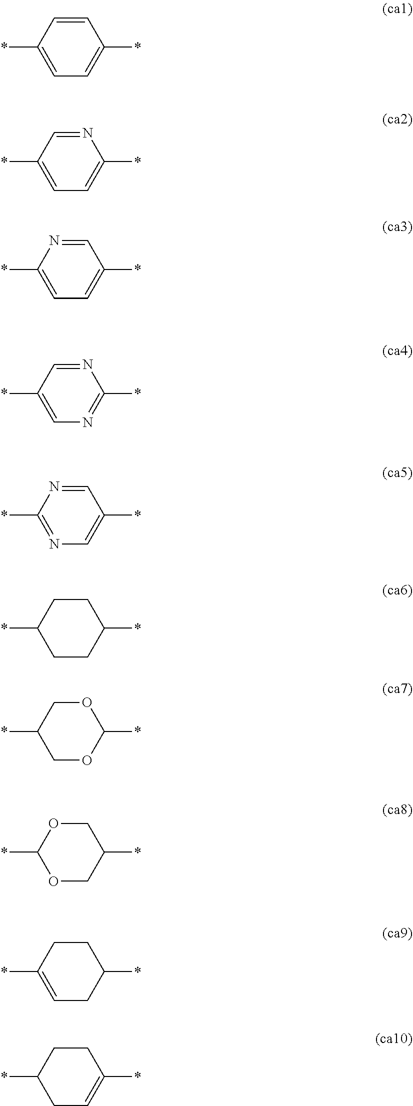
in Formulae (ca1) to (ca10), * represents a bonding position to another group, a left-side bonding site corresponds to a left-side bonding site in A, B, and C of Formula ((ca1), a right-side bonding site corresponds to a right-side bonding site in A, B, and C of Formula (ca), and a hydrogen atom bonded to a carbon atom that forms a ring in Formulae (ca1) to (ca10) may be substituted with a fluorine atom or a methyl group.

16. The liquid crystal composition according to claim 2,
wherein a dispersion term δd of a Hansen solubility parameter of the surfactant is in a range of 15.5 to 17.5.

17. The liquid crystal composition according to claim 2,
wherein the liquid crystalline compound is a high-molecular-weight liquid crystalline compound.

18. A liquid crystal layer formed of the liquid crystal composition according to claim 2.

19. A laminate comprising at least:
a photoalignment layer; and
the liquid crystal layer according to claim 18 provided on the photoalignment layer,
wherein the liquid crystalline compound included in the liquid crystal layer is immobilized in a horizontally aligned state.

20. The laminate according to claim 19,
wherein a content of the dichroic substance included in the liquid crystal layer is 3% to 35% by mass with respect to a total solid content of the liquid crystal layer.
